(19) United States
(12) Patent Application Publication
(10) Pub. No.: US 2025/0005413 A1
(43) Pub. Date: Jan. 2, 2025

(54) MODULAR AND SCALABLE QUANTUM COMPUTER

(71) Applicant: International Business Machines Corporation, Armonk, NY (US)

(72) Inventor: Shawn Anthony Hall, Pleasantville, NY (US)

(21) Appl. No.: 18/343,233

(22) Filed: Jun. 28, 2023

(51) Int. Cl. G06N 10/40; H05K 7/20

(52) U.S. Cl. CPC G06N 10/40; H05K 7/20

(57) ABSTRACT

Systems and techniques that facilitate scalable cryostats and cryogenic systems are provides. In an embodiment, a cryogenic system can comprise a plurality of unit cells joined together, wherein each unit cell comprises: a frame; and at least one temperature shell; wherein frames from adjacent unit cells are connected in a vacuum-tight manner to form a continuous, global vacuum enclosure, and temperature shells from adjacent unit cells are connected to form a continuous, global temperature shell.

### BACKGROUND

The subject disclosure relates to cryostats, and more specifically modular cryostats to enable scalable quantum computers.

### SUMMARY

The following presents a summary to provide a basic understanding of one or more embodiments of the invention. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, systems, devices and/or method that facilitate modular cryostats that facilitate scalable quantum computers are described.

According to an embodiment, a cryogenic system can comprise a plurality of unit cells joined together, wherein each unit cell comprises: a frame; and at least one temperature shell; wherein frames from adjacent unit cells are connected in a vacuum-tight manner to form a continuous, global vacuum enclosure, and temperature shells from adjacent unit cells are connected to form a continuous, global temperature shell. An advantage of such a system is that the plurality of unit cells allow for greater scalability of the cryogenic system, as more unit cells can be joined together in order to create a larger cryogenic system, as opposed to having to build and an entirely new larger cryostat.

In some embodiments, a unit cell can further comprise at least one cryogenic payload comprising a quantum device and at least one superconducting link cable coupled to a first quantum device of a first unit cell in the plurality of unit cells and to a second quantum device of a second unit cell in the plurality of unit cells. An advantage of such a system is that it allows for the superconducting link cable to be located within the global temperature shell, thereby enabling larger quantum computers built from multiple quantum devices.

According to another embodiment, a cryogenic system can comprise a plurality of unit cells joined together, wherein each unit cell comprises: a frame; a plurality of nested temperature shells at a plurality of temperature levels; at least one cryogenic cooling unit; and at least one cryogenic payload located within at least one of the different temperature levels, that is cooled by the at least one cryogenic cooling unit; wherein frames from adjacent unit cells are connected in a vacuum-tight manner to form a continuous, global vacuum enclosure, and at each temperature level, temperature shells from adjacent unit cells are connected to form a continuous, global temperature shell. An advantage of such a system is that the plurality of unit cells allows for greater scalability of the cryogenic system, as more unit cells can be joined together in order to create a larger cryogenic system, as opposed to having to build and an entirely new larger cryostat.

According to another embodiment, a cryogenic system can comprise a plurality of unit cells joined together, wherein each unit cell comprises: a frame assembly comprising at least one door that forms a vacuum-tight seal when closed; at least one temperature shell suspended from the frame assembly; at least one cryogenic cooling unit; and at least one cryogenic payload located within the at least one temperature shell, wherein frames from adjacent unit cells are connected in a vacuum-tight manner to form a continuous, global vacuum enclosure, and temperature shells from adjacent unit cells are connected to form a continuous, global temperature shell. An advantage of such a system is that the plurality of unit cells allows for greater scalability of the cryogenic system, as more unit cells can be joined together in order to create a larger cryogenic system, as opposed to having to build and an entirely new larger cryostat.

### DESCRIPTION OF THE DRAWINGS

FIG. 1 illustrates a cutaway view of an existing dilution refrigerator.

FIG. 2 illustrates a cutaway view of a juxtaposition of two existing dilution refrigerators.

FIG. 3 illustrates an assembly view of a generic unit-cell embodiment in accordance with one or more embodiments described herein.

FIG. 4 illustrates an exploded view of a generic unit-cell embodiment in accordance with one or more embodiments described herein.

FIG. 5 illustrates a frame assembly in accordance with one or more embodiments described herein.

FIG. 6 illustrates a frame assembly and an end-wall assembly in accordance with one or more embodiments described herein.

FIG. 7 illustrates a generic Field-Replacement-Unit (FRU) assembly in accordance with one or more embodiments described herein.

FIG. 8 illustrates an assembled view of a generic thermal-shell assembly in accordance with one or more embodiments described herein.

FIG. 9 illustrates an exploded view of a generic thermal-shell assembly in accordance with one or more embodiments described herein.

FIG. 10A-10D illustrates assembled and exploded views of two generic thermal-shell assemblies in accordance with one or more embodiments described herein.

FIG. 11A-11G illustrates exploded and assembled views of a series of end thermal shields in accordance with one or more embodiments described herein.

FIG. 12 illustrates a cutaway view of a generic embodiment in accordance with one or more embodiments described herein.

FIGS. 13A-13D illustrate generic-FRU removal in accordance with one or more embodiments described herein.

FIG. 14 illustrates an assembled view of a fully featured embodiment in accordance with one or more embodiments described herein.

FIG. 15 illustrates an exploded view of a fully featured embodiment in accordance with one or more embodiments described herein.

FIGS. 16A and 16B illustrate a fully featured unit cell in accordance with one or more embodiments described herein.

FIGS. 17A and 17B illustrate a fully featured FRU assembly in accordance with one or more embodiments described herein.

FIG. 18 illustrates another view of a fully featured skylight assembly in accordance with one or more embodiments described herein.

FIG. 19 illustrates a fully featured, shield-less FRU assembly in accordance with one or more embodiments described herein.

FIG. 20 illustrates another view of a fully featured, shield-less FRU assembly in accordance with one or more embodiments described herein.

FIG. 21 illustrates an exploded view of a payload assembly in accordance with one or more embodiments described herein.

FIG. 22 illustrates an exploded view of a payload-electronics assembly of in accordance with one or more embodiments described herein.

FIG. 23 illustrates an assembled view of a payload-electronics assembly and connecting cables in accordance with one or more embodiments described herein.

FIG. 24 illustrates a front-cutaway view of a fully featured embodiment in accordance with one or more embodiments described herein.

FIG. 25 illustrates a close-up front-cutaway view of a fully featured embodiment.

FIG. 26 illustrates a top-cutaway view of a fully featured embodiment.

FIG. 27 illustrates a cutaway top view of an embodiment with a plurality of payloads per unit cell.

FIGS. 28A and 28B illustrate a parallel frame and a wedge frame in accordance with one or more embodiments described herein.

FIG. 29A-29D illustrate various combinations of parallel frames and wedge frames in accordance with one or more embodiments described herein.

FIG. 30 illustrates the use of parallel frames and wedge frames in accordance with one or more embodiments described herein.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

To solve computational problems unachievable by classical computers, a quantum computer comprises a large number N of physical qubits. Historically, quantum computers comprising superconducting qubits have been small enough that all N qubits and supporting equipment fit in a single existing cryostat. However, because N continually grows as quantum technology progresses, the number of qubits is now so large that a single monolithic refrigerator can no longer accommodate all of them. As N continues to grow, building ever-larger dilution refrigerators utilizing existing designs grows increasingly expensive, and leads to hardware sizes that are ultimately untenable, cumbersome, and unmanageable. Accordingly, when N exceeds the number of qubits that can be packaged together—a number that depends on engineering limits of qubit-supporting infrastructure (including chips, circuit-boards, connectors, cabling, and cooling equipment)—then the N qubits are divided into a plurality of groups called payloads. Yet, for a quantum computer to be effective, payloads must be able to send electromagnetic signals to their neighbors over quantum-link cables that are as short as possible, and which remain superconducting over their entire length to minimize loss.

However, it is difficult to build such a multi-payload quantum computer simply by juxtaposing a plurality of conventional dilution refrigerators, each containing a payload, and connecting quantum-link cables between them, because to travel between such refrigerators, a portion of each cable would have to be at room temperature and thus would be far too lossy, because no superconducting materials are currently known to exist at ambient temperature and pressure. Moreover, cables between existing refrigerators would be excessively long, which is also a source of loss.

In one or more embodiments described herein, systems, devices and/or method that facilitate modular cryostats that facilitate scalable quantum computers are described that address the above-described problems with existing dilution refrigerators and cryostats. In one or more embodiments described herein, a cryogenic system can comprise a plurality of unit cells joined together, wherein each unit cell comprises: a frame; and at least one temperature shell; wherein frames from adjacent unit cells are connected in a vacuum-tight manner to form a continuous, global vacuum enclosure, and temperature shells from adjacent unit cells are connected to form a continuous, global temperature shell. Accordingly, the unit cell structure of the cryogenic system enables scalability of the system as more unit cells can be added or removed from the system to enable scalability to the desired size of cryostat. Furthermore, in one or more embodiments described herein, the cryogenic system can further comprise at each end of the plurality of unit cells an end frame, such that the plurality of frames and end frames together form a vacuum-tight vessel; and an end cap for the global temperature shell at each end of the plurality of unit cells, such that the global temperature shell and end caps form a substantially closed, radiation-resistant thermal enclosure. As used herein the term “thermal shell” can be interchangeable with temperature shell.

For example, in one or more embodiments herein, a modular, scalable quantum computer can comprise an array of n+4 unit cells arrayed along an imaginary x axis of an imaginary Cartesian xyz coordinate system where +z is vertical upward, and where n is a integer greater than or equal to zero. Denoting various cell types by letters, the array can comprise cells {A B D E}, or {A B C₁ C₂ D E}, or {A B C₁ C₂ C₃ D E}, or more generally {A B C₁ C₂ . . . Cₙ D E}, where C₁, C₂, . . . , Cₙ are instances of C and n of the cells are type C. In this nomenclature, A is an unpopulated, left-end unit cell; B is a populated unit cell with left-end thermal shields; C is a default, populated unit cell; D is a populated unit cell with right-end thermal shields, and E is an unpopulated, right-end unit cell. Each unit cell, whether type A, B, C, D, or E, can comprise a frame assembly that can comprise a frame, two hinged, vacuum-sealed door assemblies abutting the +y and −y faces of the frame, and a skylight assembly abutting the +z face of the frame. The frame assembly can be identical for all cell types, and the frames of adjacent cells can be abutted in a vacuum-tight manner. Cell A can comprise a left-end-wall assembly that is affixed to the −x face of A's frame in a vacuum-tight manner; likewise, cell E can comprise a right-end-wall assembly that is affixed to the +x face of E's frame in a vacuum-tight manner. Consequently, the array of frame assemblies and end-wall assemblies together can form a vacuum-tight shell. Cell types B, C, and D each can comprise a dilution-refrigerator assembly that can be affixed to the skylight assembly, such that various arrangements of refrigeration equipment and other infrastructure can be accommodated by re-designing the skylight assembly only, but without re-designing the frame and door assemblies. Cell types B, C, and D can each further comprise a quantum payload assembly comprising N_{Q} qubits as well as the electronic infrastructure necessary to support them, the payload assembly being affixed to a base-temperature flange of the dilution-refrigerator.

The dilution-refrigerator assembly in each cell B, C, D can comprise an array of thermal side-shields on its +y and −y faces. Additionally, the dilution-refrigerator assembly in cell B can comprise an array of left-end thermal shields on its-x face, and the dilution-refrigerator assembly in cell D can comprise an array of right-end thermal shields on its +x face. Thus, the entire array of refrigerators can be surrounded by a continuous set of thermal shields on all sides, thereby providing one large, evacuated, thermally shielded space in which all the payloads of cells {B C₁ C₂ . . . Cₙ D} reside, with no barriers between payloads. Consequently, superconducting quantum-link cables (and other equipment if desired) can be connected between payloads without encountering barriers and without leaving the confines of the innermost, base-temperature shell of the aggregated dilution refrigerators, thereby ensuring that the quantum-link cables remain superconducting. Furthermore, the link cables can be relatively short, thereby both decreasing material and production costs of the link cables, as well as improving performance.

Additionally, because it is modular, the unit cell can be designed to be physically manageable; for example, one of its dimensions can be relatively small so that a unit cell can fit through typical doorways. Moreover, in one or more embodiments, the unit cell can be designed to be flexible, such that various types of refrigeration equipment, payload, and signal-delivery can be accommodated without re-designing any of the frame assembly except the skylight assembly. In addition, the modularity of the cells further enables easier maintenance and repairs, because the dilution-refrigeration unit and payload of any cell can, by virtue of the skylight assembly, be withdrawn from the frame for servicing or replacement. Modularity of the cells also reduces design effort and expense required to scale the quantum computer to accommodate a growing number N of qubits, because it suffices merely to add more unit cells C to the array.

Variations of one or more embodiments are also envisioned. For example, if the left-end thermal shields and right-end thermal shields do not protrude beyond the confines of cells B and D, respectively, then cells A and E can be omitted, leaving {B C₁ C₂ . . . Cₙ D}, in which case the left-end-wall assembly can be affixed to the −x face of cell B, and the right-end-wall assembly can be affixed to the +x face of cell D. As another example, if the aforesaid flexibility in the arrangement of cooling equipment and payload-wiring infrastructure is not needed, and the aforesaid option to withdraw the dilution-refrigeration and payload from the frame for servicing and replacement is not needed, then the skylight assembly can be eliminated in favor of connecting refrigeration equipment and other infrastructure directly to the +z surface of the frame.

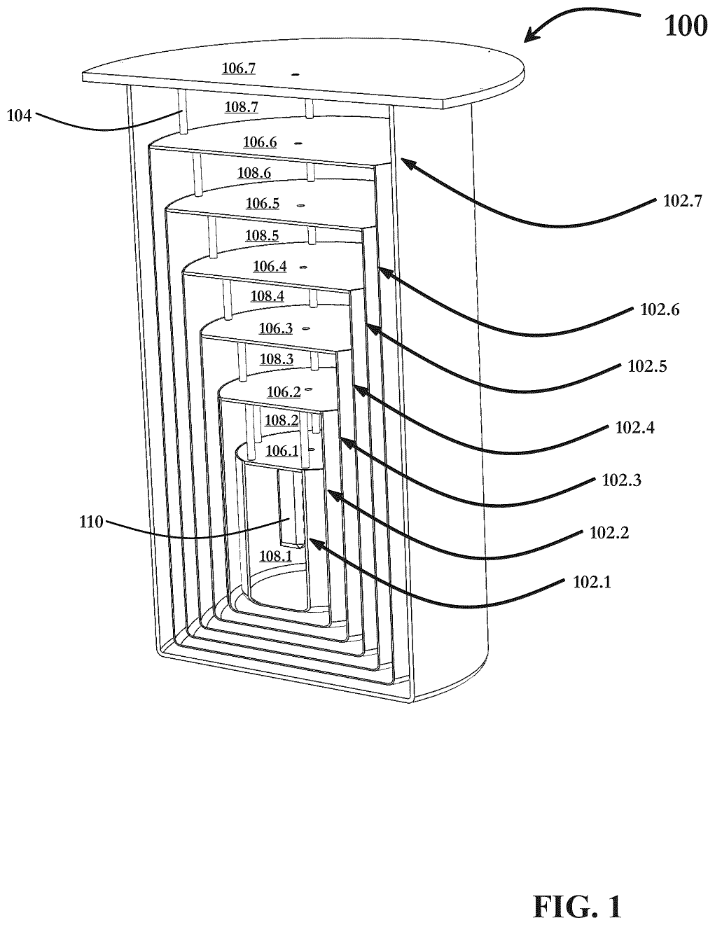

As illustrated in FIG. 1, an existing dilution refrigerator 100 comprises a plurality of nested shells 102 (e.g., 102.1, 102.2, . . . , 102.7) connected to each other with standoffs 104, where each shell comprises a flange 106 and a can 108. Standoffs 104 must be long enough to prevent undue heat conduction between shells and to accommodate refrigeration equipment not shown. By means of the refrigeration equipment, the various shells 102 are held at different temperatures: outermost shell 102.7 is held at a room temperature such as T₇=300K; innermost shell 102.1 is held at a base temperature such as T₁=20 mK; and intervening shells 102.2, . . . , 102.6 are held at intermediate temperatures T₂, . . . , T₆, respectively, such as 100 mK, 800 mK, 4K, 10K, and 50K, respectively. Inner cans 108.1, 108.2, . . . , 108.6 are radiation shields that prevent higher-temperature radiation from falling on lower-temperature shells and thereby overwhelming the refrigeration equipment with excessive heat load. Outermost can 108.7 is a vacuum enclosure, because cryogenically cooled equipment must be in vacuum to avoid frozen water and air. To function properly, a payload 110 comprising superconducting qubits must be held at temperature T₁ and must avoid radiation from higher temperature; consequently, payload 110 must exist inside the innermost shell 102.1, as shown. To gain access to payload 110 for service, all cans 108 are removed one by one, starting with the vacuum can 108.7. Likewise, after servicing, prior to restarting the quantum computer 100, all cans 108 are replaced, starting with innermost can 108.1.

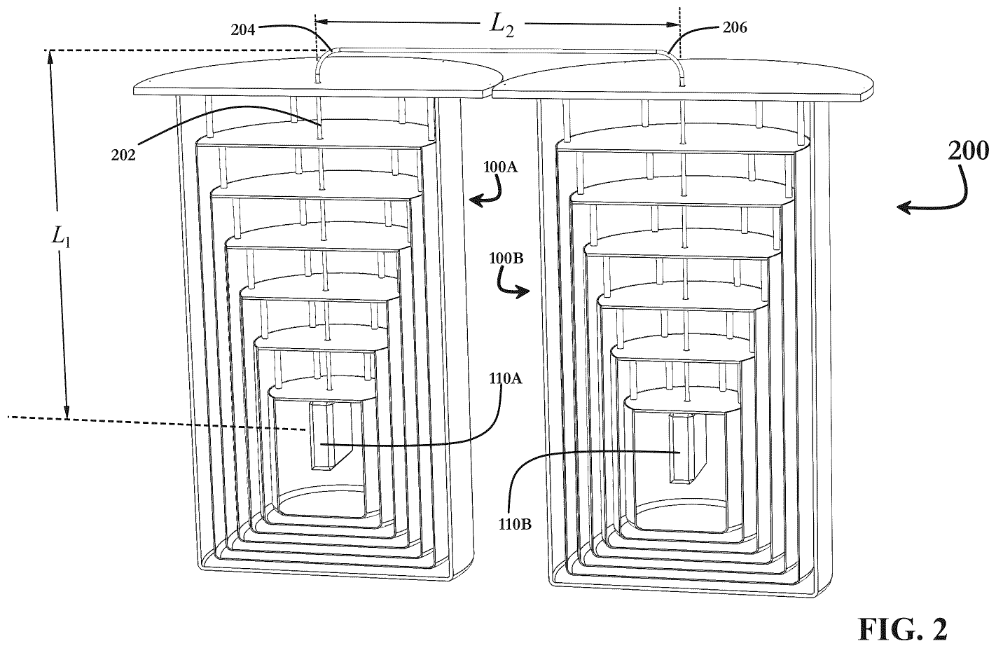

Referring to FIG. 2, consider a juxtaposition 200 of two existing dilution refrigerators 100A and 100B that house quantum payloads 110A and 110B, respectively. Because of the topology of the conventional refrigerators, a quantum-link cable 202 cannot travel directly between payloads 110A and 110B because cans 108 are impenetrable barriers that must also be, as explained above, removable, which precludes the notion of passing cables through small holes in the cans. Consequently, cable 202 comprises three portions as shown: a first portion of Manhattan length L₁ that extends from payload 110A to corner 204, a second portion of Manhattan length L₂ that extends from corner 204 to corner 206, and a third portion of Manhattan length L₁ that extends from corner 206 to payload 110B. Unfortunately, over a considerable portion of cable 202's length, its conducting elements do not superconduct despite being composed of superconducting material, because said portion is at a temperature above the superconducting-transition temperature of known materials suitable for cables. In particular, the second portion is at room temperature, where no known materials superconduct. Thus, cable 202 is unsuitable to carry quantum signals from payload to payload, because the loss of quantum information is excessive. Moreover, cable 202 is quite long, having length L=2L₁+L₂, which further incurs loss. For example, in an existing dilution refrigerator, L₁≥1100 mm and L₂≥865 mm, whence L≥3,065 mm, which is far longer than desired for a low-loss, quantum-link cable, thereby degrading performance.

Consequently, to enable quantum computers in which N is so large that qubits must be grouped into physically separated payloads that are connected by quantum-link cables, it is desirable to find a replacement for a conventional dilution refrigerator that eliminates the problems just described. Specifically, because operation at non-superconducting temperatures and increases in cable length increase loss, it is desirable to eliminate barriers between payloads so that payload-to-payload quantum-link cables can remain superconducting over their entire length, and so their length can be relatively short (e.g., approximately one meter in length). It is also desirable for the replacement technology to be physically manageable to facilitate moving the equipment, navigating it through doorways, and installing it, manageability that is lacking in large conventional refrigerators, because they are typically large in all three dimensions.

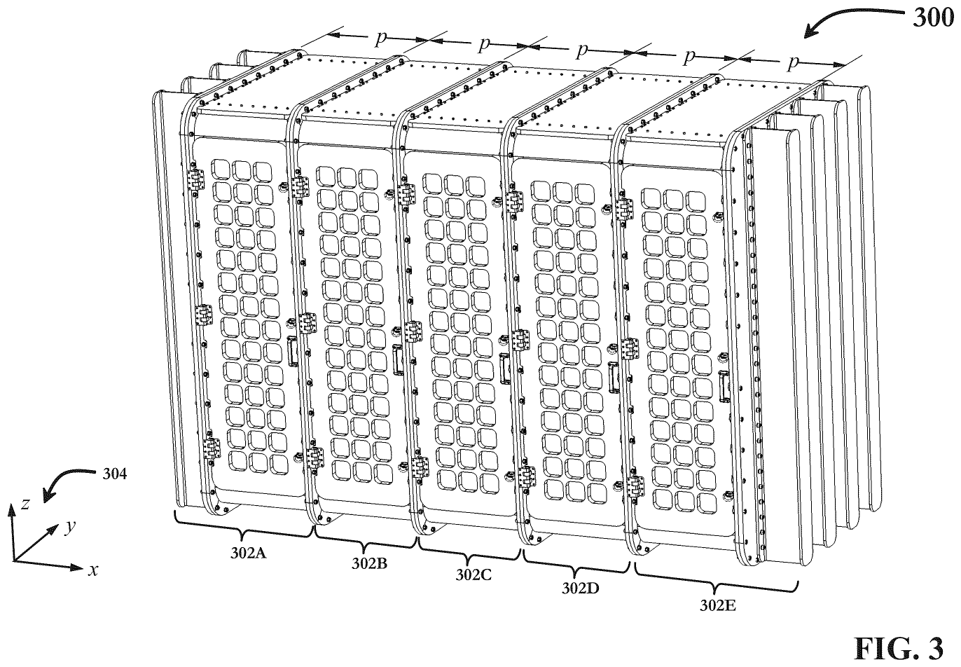

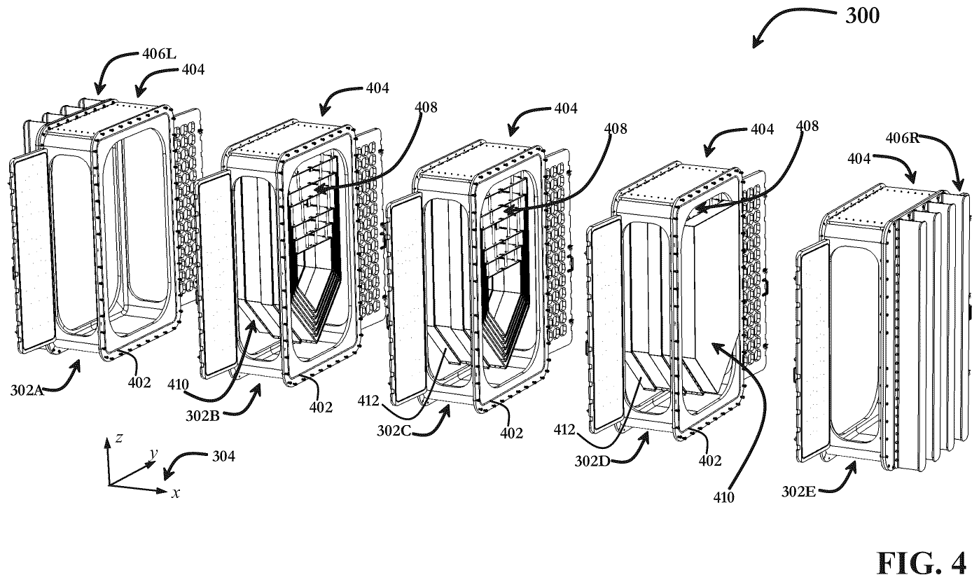

Accordingly, a first, “generic” embodiment 300 is illustrated in FIG. 3 (assembled) and FIG. 4 (exploded). In generic embodiment 300, certain elements required for an actual quantum computer or other cryogenic applications are deliberately missing, and others are shown generically without decorating them with features specific to a particular arrangement of the missing elements, thereby to emphasize the flexibility and adaptability of the generic structure to a variety of quantum-computer designs and to other applications. An example of a fully featured, quantum-computer design that derives from generic embodiment 300 is shown further below.

As shown, generic structure 300 can comprise a unit-cell array of five unit cells 302A, 302B, 302C, 302D and 302E that are arrayed at pitch p along an imaginary x direction of an imaginary Cartesian xyz coordinate system 304. The unit-cell array can comprise an unpopulated, left-end unit cell 302A; a populated, left-thermal-shield unit cell 302B; a populated, default unit cell 302C; a populated, right-thermal-shield unit cell 302D; and an unpopulated, right-end unit cell 302E. For brevity, these different variants of unit cell 302 can be referred to succinctly by alphabetic suffix alone; that is, 302A may be referred to as “A”, 302B as “B”, 302C as “C”, 302D as “D”, and 302E as “E”. Adjacent cells {A B C D E} can be abutted to form a vacuum-tight seal therebetween by means of O-Rings 402 illustrated on FIG. 4.

The unit-cell array {A B C D E} shown in FIG. 3 and FIG. 4 is merely exemplary. Other possible arrangements include, {A B D E}, {A B C₁ C₂ D E}, {A B C₁ C₂ C₃ D E}, and more generally {A B C₁ C₂ . . . Cₙ DE}, where C₁, C₂, . . . , Cₙ are instances of C and n is any integer greater than or equal to zero. That is, the cell array can comprise n+2 populated cells {B C₁ C₂ . . . . Cₙ D} and two unpopulated cells {A E}.

FIG. 4 illustrates an exploded view of generic embodiment 300 in accordance with one or more embodiments described herein. As shown in FIG. 4 each type of unit cell—A, B, C, D, and E—can comprise a frame assembly 404 that is identical for all types of cells. Unpopulated, left-end cell A can comprise a left-end-wall assembly 406L, whereas unpopulated, right-end cell E can comprise a right-end-wall assembly 406R. Each populated cell B, C, or D can comprise a generic refrigerator assembly 408. Left-thermal-shield cell B additionally can comprise a first array of end thermal shields 410. Default cell C additionally can comprise a first set of bridge shields 412 that bridge between cells B and C. Right-thermal-shield cell D additionally can comprise a second array of end thermal shields 410, as well as a second set of bridge shields 412 that bridge between cells C and D.

In generic embodiment 300, refrigerator assembly 408 deliberately comprises neither a quantum payload, nor cooling means to chill it, nor wiring means to connect it to external equipment or to other payloads. These missing elements will be described in a later embodiment in which the generic hardware of generic embodiment 300 is specialized to include a particular type of payload, particular cooling means, and particular wiring means, thereby to demonstrate how a particular design for a quantum computer may be derived from the generic, generic embodiment 300. Use of generic embodiment 300 for other cryogenic applications, including those unrelated to quantum computing, is envisioned.

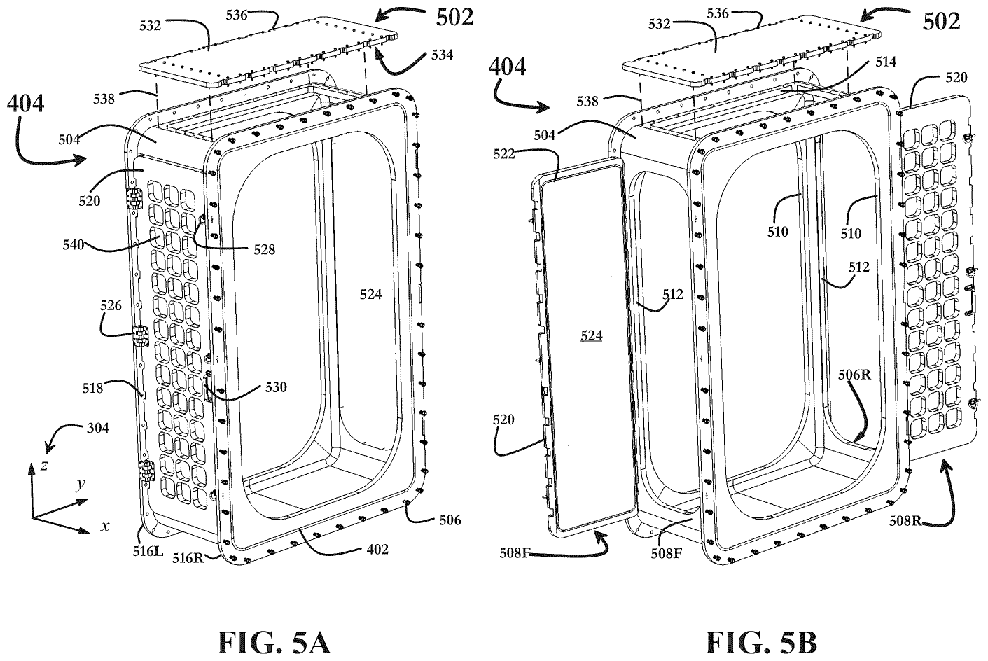

FIGS. 5A and 5B illustrate a frame assembly in accordance with one or more embodiments described herein. As shown, FIG. 5A illustrates a closed-door configuration of a frame assembly 404, as well as a generic skylight assembly 502. FIG. 5B illustrates the same two assemblies, but with frame assembly 404 in an open-door configuration. Frame assembly 404 can comprise a frame 504, an O-ring 402, a plurality of O-ring bolts 506, a front-door assembly 508F, and a rear-door assembly 508R that is identical to 508F.

Referring to FIG. 5B, frame 504 can be shell-like in structure, comprising a large cutout 510 through each of its +x and −x faces, a door cutout 512 in each of its +y and −y faces, and a skylight cutout 514 through its +z face. Referring to FIG. 5A, a −x portion of frame 504 comprises a left flange 516L; similarly, a +x portion of frame 504 comprises a right flange 516R that is identical to flange 516L. Each of 516L and 516R can be perforated with a plurality of holes 518 that engage O-ring bolts 506 used to compress O-ring 402 when frame assemblies are abutted as illustrated in FIG. 3.

Referring to both FIG. 5A and FIG. 5B, door assembly 508F and/or 508R can comprise a door 520, a door O-ring 522 that rests in a groove cut into an inner door surface 524 for the purpose of providing a vacuum seal to frame 504, a plurality of hinges 526, a plurality of latches 528, and a handle 530. Skylight assembly 502 can comprise a skylight plate 532, an skylight O-ring 534 (not visible) that rests in a groove (not visible) cut into the −z face (not visible) of plate 5326, and a plurality of skylight screws 536 that affix skylight plate 532 to the +z face of frame 504 (as illustrated by a series of imaginary dashed lines 538 on FIG. 5A and FIG. 5B), thereby compressing O-ring 534 to form a vacuum seal. Door 520 can comprise a plurality of blind cutouts 540 to reduce weight without undue sacrifice of stiffness.

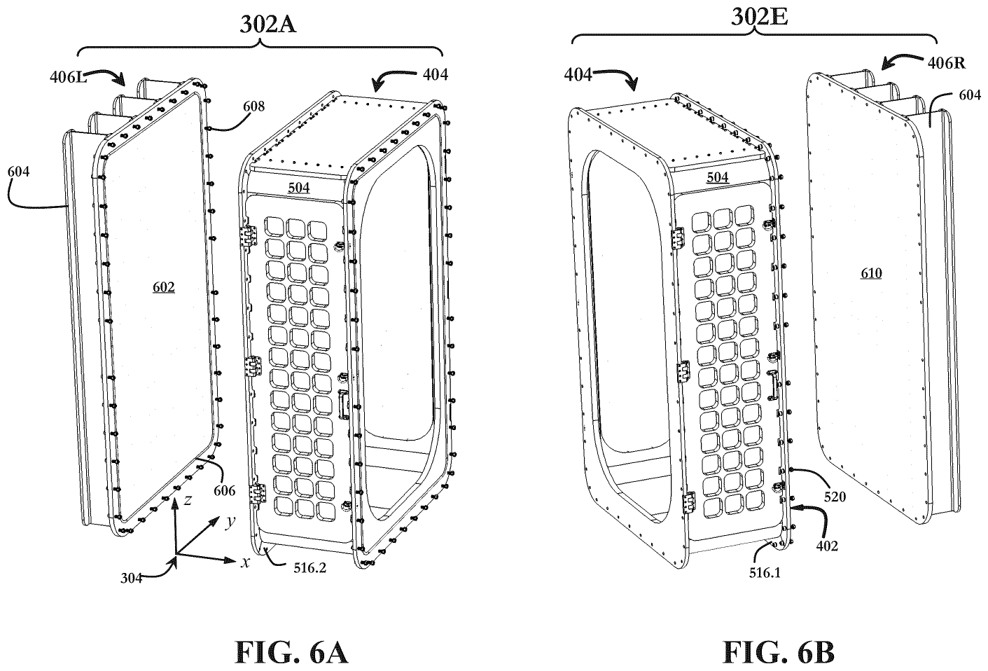

FIGS. 6A and 6B illustrate a frame assembly and an end-wall assembly in accordance with one or more embodiments described herein. Referring to FIG. 6A, left-end-wall assembly 406L can comprise left-end wall 602, a plurality of I-beams 604, a plurality of bolts (not shown) to affix I-beams 604 to left end wall 602, an O-ring 606 that rests in an O-Ring groove cut into the +x face of wall 602, and a plurality of bolts 608. O-Ring 606, together with bolts 608 that engage holes in wall 602 and mating holes in flange 516L, can be used to affix left-end-wall assembly 406L to frame assembly 404, thereby to achieve a vacuum seal therebetween.

Referring to FIG. 6B, right-end-wall assembly 406R can comprise right-end wall 610, a plurality of I-beams 604, and a plurality of bolts (not shown) to affix I-beams 604 to right end wall 610. Aforesaid O-Ring 402 and bolts 520 of cell E's frame assembly 404, which engage holes in wall 610 and mating holes in flange 516R, can be used to affix right-end-wall assembly 406R to frame assembly 404, thereby to achieve a vacuum seal therebetween.

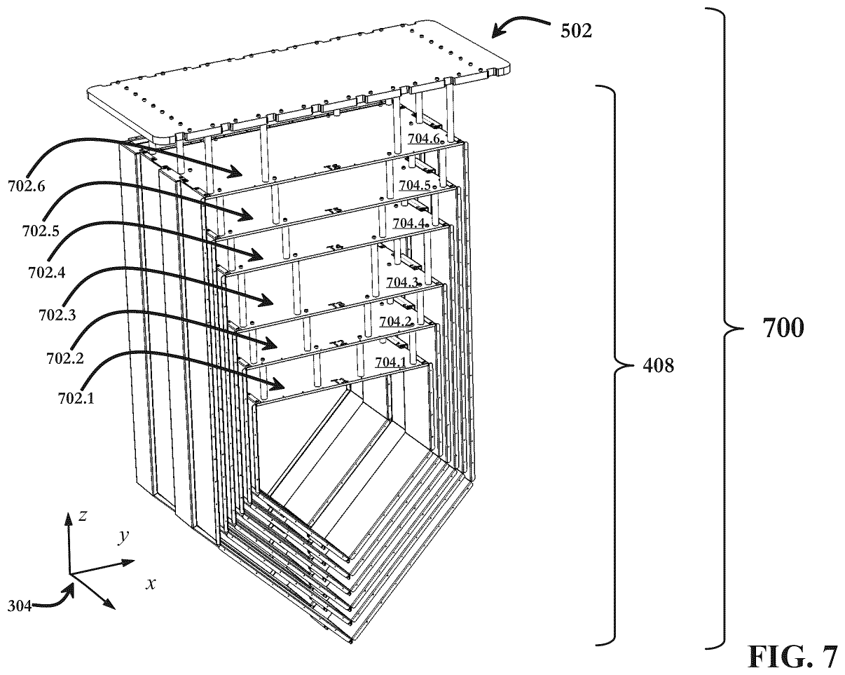

FIG. 7 illustrates a generic Field-Replacement-Unit (FRU) Assembly of a cell in accordance with one or more embodiments described herein. As shown in FIG. 7, generic Field-Replacement-Unit (FRU) 700 can comprise generic dilution-refrigerator assembly 408 and generic skylight assembly 502. Refrigerator assembly 408 can comprise an m-fold array of nested thermal-shell assemblies 702 that are held, by refrigeration equipment not specified in the generic assembly 408, at various cryogenic temperatures. For example, for the case m=6 shown, assembly 408 can comprise a first thermal-shell assembly 702.1 held at a first temperature T₁, a second thermal-shell assembly 702.2 held at second temperature T₂, a third thermal-shell assembly 702.3 held at third temperature T₃, a fourth thermal-shell assembly 702.4 held at a fourth temperature T₄, a fifth thermal-shell assembly 702.5 held at a fifth temperature T₅, and a sixth thermal-shell assembly 702.6 held at a sixth temperature T₆, where T₁<T₂<T₃<T₄<T₅<T₆. For example, in quantum-computing applications, the following temperatures are typical: T₁≈20 mK, T₂≈100 mK, T₃≈700 mK, T₄≈4 K, T₅≈10 K, T₆≈50 K. However, use of any temperature or temperature range is envisioned. Thermal shell 702.1 can comprise a first top plate 704.1, thermal shell 702.2 can comprise a second top plate 704.2, thermal shell 702.3 can comprise a third top plate 704.3, thermal shell 702.4 can comprise a fourth top plate 704.4, thermal shell 702.5 can comprise a fifth top plate 704.5; and thermal shell 702.6 can comprise a sixth top plate 704.6.

FIG. 8 illustrates an assembled view of a generic thermal-shell assembly in accordance with one or more embodiments. As shown, FIG. 8 illustrates an assembled view of generic thermal-shell assembly 702.1, which can comprise a thermal-flange assembly 802, a first assembly of thermal shields 804a and an identical second assembly of thermal shields 804b. Each of the other thermal-shell assemblies—702.2 through 702.6—can be analogous to 702.1 in various sizes.

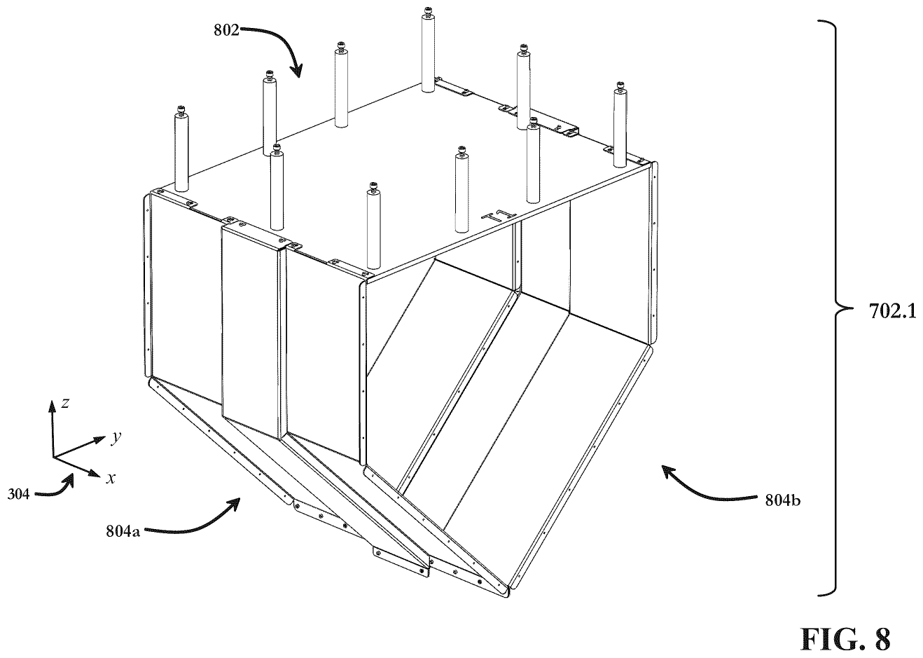

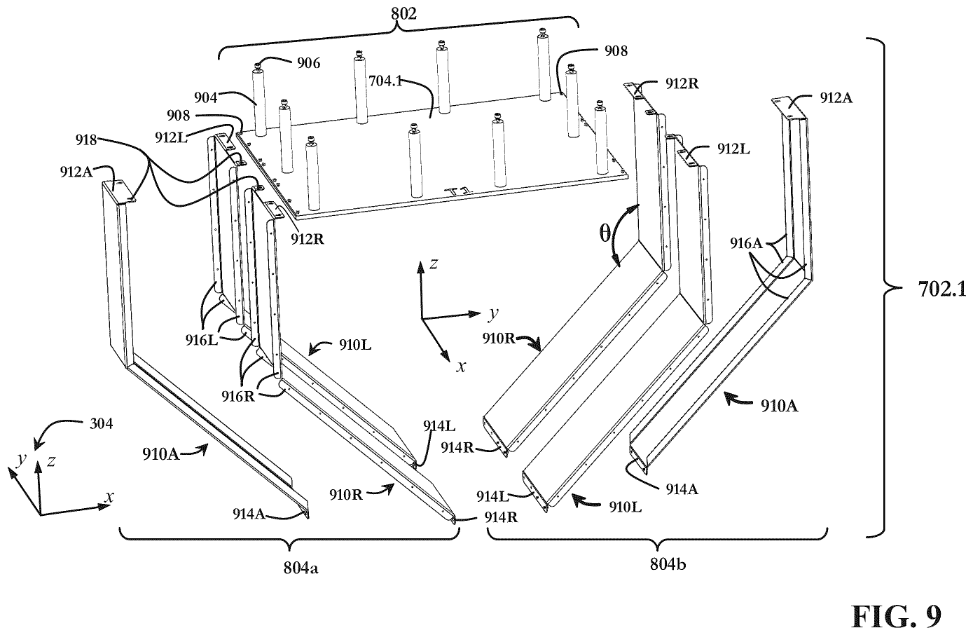

FIG. 9 illustrates an exploded view of a generic thermal-shell assembly in accordance with one or more embodiments. Thermal-flange assembly 802 can comprise top plate 704.1, a plurality of top-plate standoffs 904, a plurality of standoff screws 906, and a plurality of shield-attach screws 908. Each of the thermal-shield assemblies 804a and 804b can comprise a left-handed thermal shield 910L that can comprise a left-handed top flange 912L, a left-handed bottom flange 914L, and a set of left-hand side flanges 916L; a right-handed thermal shield 910R that can comprise a right-handed top flange 912R, a right-handed bottom flange 914R, and a set of right-hand side flanges 916R; and an auxiliary shield 910A that can comprise a auxiliary top flange 912A, an auxiliary bottom flange 914A, and a set of auxiliary side flanges 916A that, in the assembled structure illustrated in FIG. 8, can overlap flanges 916L and 916R, thereby forming continuous, radiation-resistant assemblies 804a and 804b of thermal shields.

Each of the bottom flanges 914L, 914R, and 914A can comprise screws and swaged nuts (not visible) that provide means to affix, at the bottom, opposing bottom flanges to each other: left-hand bottom flange 914L of assembly 804a can be thereby affixed to right-hand bottom flange 914R of assembly 804b, right-hand bottom flange 914R of assembly 804a can be thereby affixed to left-hand bottom flange 914L of assembly 804b, and bottom bridge flanges 914A of assemblies 804a and 804b can be thereby affixed to each other.

Each thermal shield 910L, 910R, and 910A can be affixed at the top to top plate 704.1: top flanges 912L, 912R, and 912A can contain keyhole slots 918 that engage screws 908, such that the −z faces of flanges 912L, 912R, and 912A abut the +z face of top plate 704.1, thereby supporting thermal shields 910L, 910R, and 910A. Tightening screws 908 can affix them. Aforesaid affixing of bottom flanges 914L, 914R, 914A to each other can occur following keyhole-slot engagement at top flanges 912L, 912R, 912A. In one or more embodiments, the thermal shell formed from thermal shields 910L, 910R and 910A can form a substantially uniform surface that includes structures with variances accounting for generally understood engineering tolerances, designs to account for manufacturability and constructability, and requirements for expansion and/or contraction due to temperature changes during cooling. For example, the temperature shell formed by thermal shields 910L, 910R and 910A can have a cross-sectional area variance within 50%.

Still referring to FIG. 9, it is anticipated that in some applications of generic embodiment 300, it can be advantageous for thermal shields 910L, 910R, and 910A to use a different value of angle θ than that illustrated, which value is θ=135°. In general, angle θ can range from 90° to 180°.

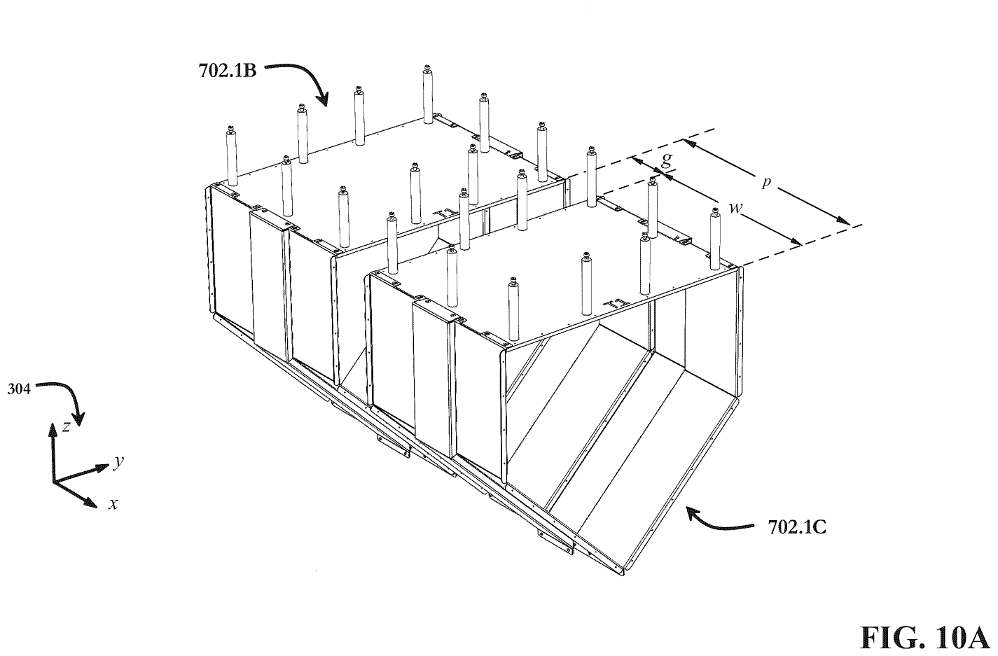

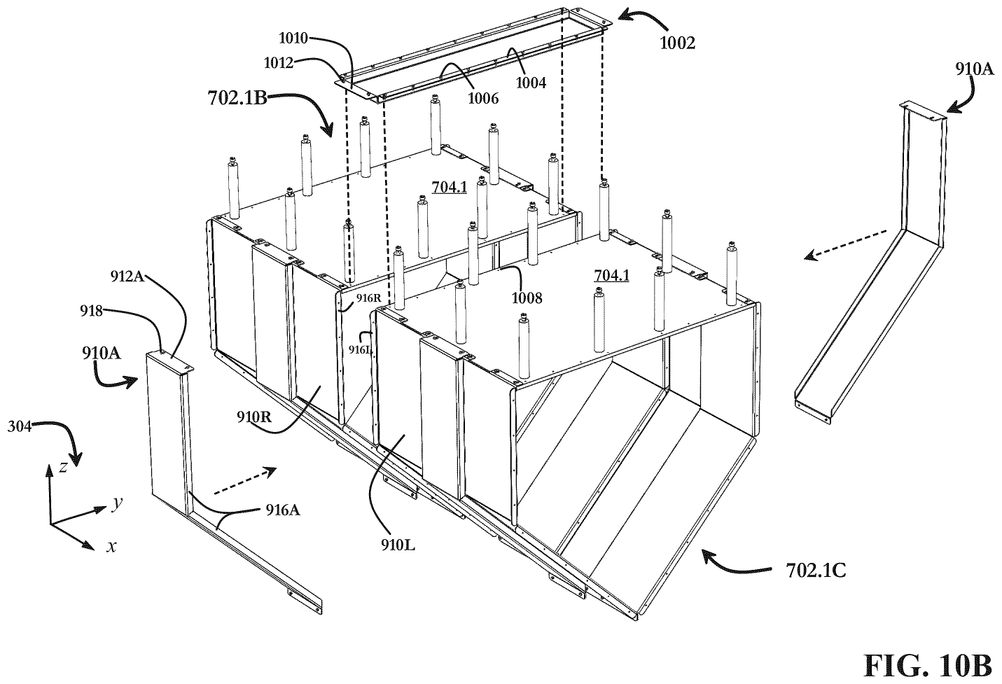

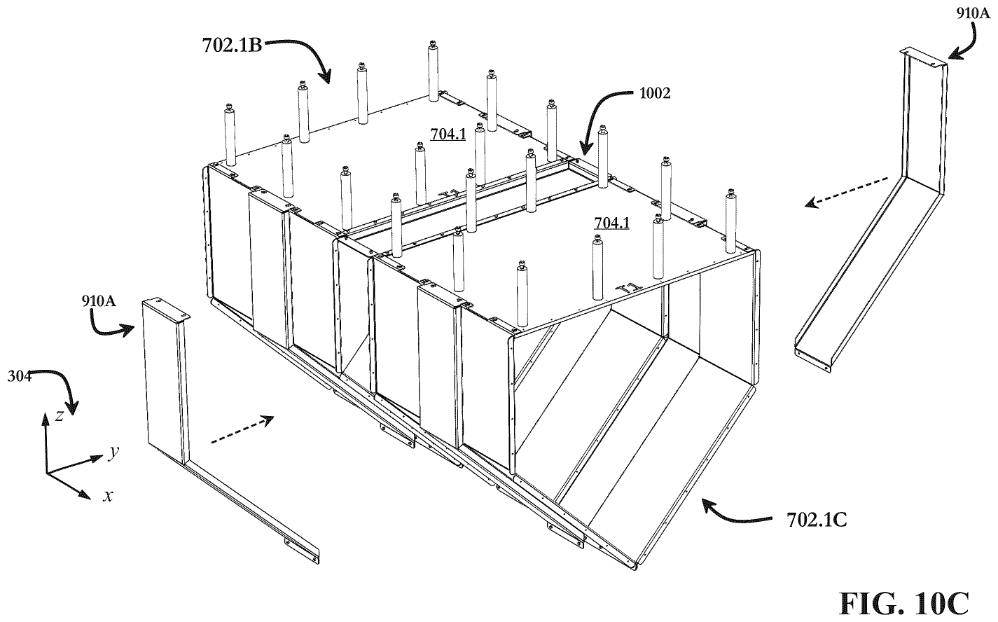

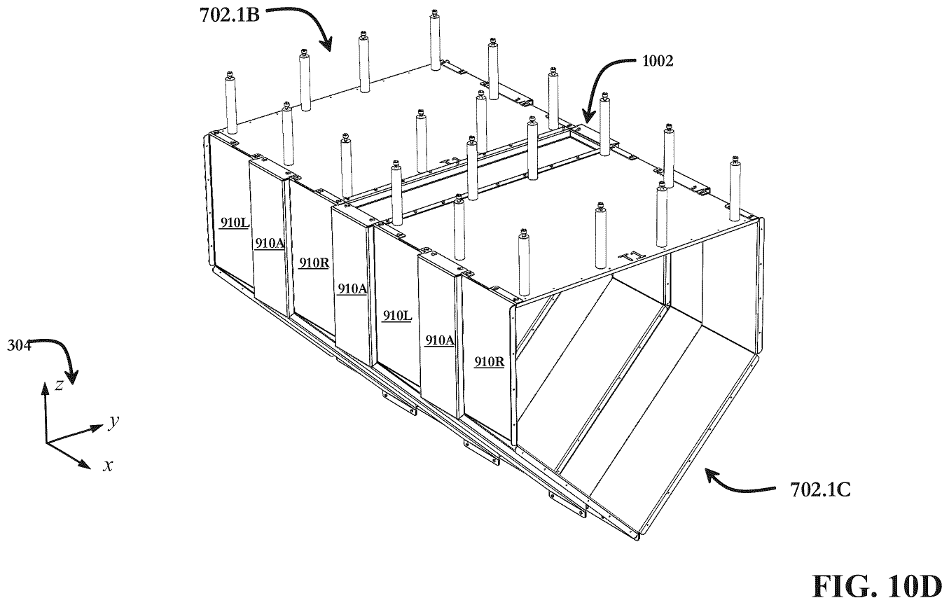

FIGS. 10A-10D illustrate assembled and exploded view of a series of end thermal shields in accordance with one or more embodiments described herein. FIG. 10A illustrates two instances of the temperature-T₁ thermal-shell assembly 702.1 belonging to two neighboring cells such as B and C, and therefore denoted 702.1B and 702.1C, respectively. In the x direction, each shell 702.1 can have width w, which is deliberately less than unit-cell pitch p for the purpose of allowing removal of refrigerator 408 and skylight assembly 502 from unit cell 302 for purposes of repair and maintenance, as further explained later. Consequently, gap g=p−w can exist between neighboring thermal shells 702.1. The same situation applies to higher-temperature thermal-shell assemblies 702.2 through 702.6; in every case, thermal-shell width can be w, which is less than unit-cell pitch p, so gap g can exist. To provide continuous thermal shields, gap g must be substantially closed for every shell 702.1 through 702.6. The following illustrates how gap g can be closed for shell 702.1; other cases are analogous.

As illustrated in FIG. 10B, which is an exploded illustration, a set of temperature-T₁ bridge shields can comprise a top-tray assembly 1002 and two instances of auxiliary shield 910A. Top-tray assembly 1002 can comprise a pair of side flanges 1004 comprising an array of screws 1006 that engage an array of tapped holes 1008 in top plates 704.1B and 704.1C, as illustrated in FIG. 10C. Top-tray assembly 1002 can further comprise a pair of end flanges 1010 that each can comprise a pair of screws 1012. Keyhole slots 918 of auxiliary shield 910A can engage screws 1012, as illustrated in FIG. 10D. Assembly of the bridge shields can proceed as suggested by FIG. 10C and FIG. 10D: top-tray assembly 1002 can be installed first, followed by auxiliary shields 910A, which can be affixed to each other at the bottom as previously described in connection with FIG. 9, and whose side flanges 916A can fit over side flanges 916L and 916R as previously described, like the lid of a shoebox. Thus, the set of bridge shields comprising tray assembly 1002 and the pair of auxiliary shields 910A can effectively close gap g illustrated in FIG. 10A. Consequently, as illustrated in FIG. 10D, the adjacent pair of thermal-shell assemblies 702.1B and 702.1C can be unified into a continuous thermal shield spanning the two adjacent unit cells B and C, a unification that can be extended to as many adjacent, populated unit cells as required, such as BCCC . . . CCCD, creating a tunnel of temperature-T1 thermal shells with no barrier across the entire array of populated unit cells. Similarly, a continuous array of shields like that those in FIG. 10D can be replicated at each temperature (e.g., T₁ through T₆), thereby creating a nested sets of tunnels across the entire array of populated unit cells.

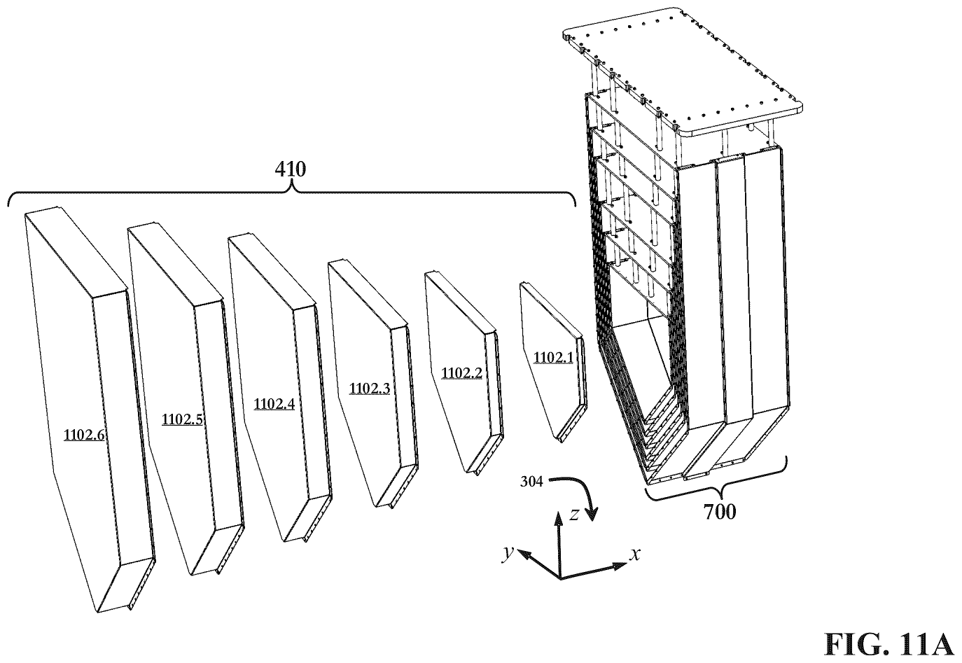

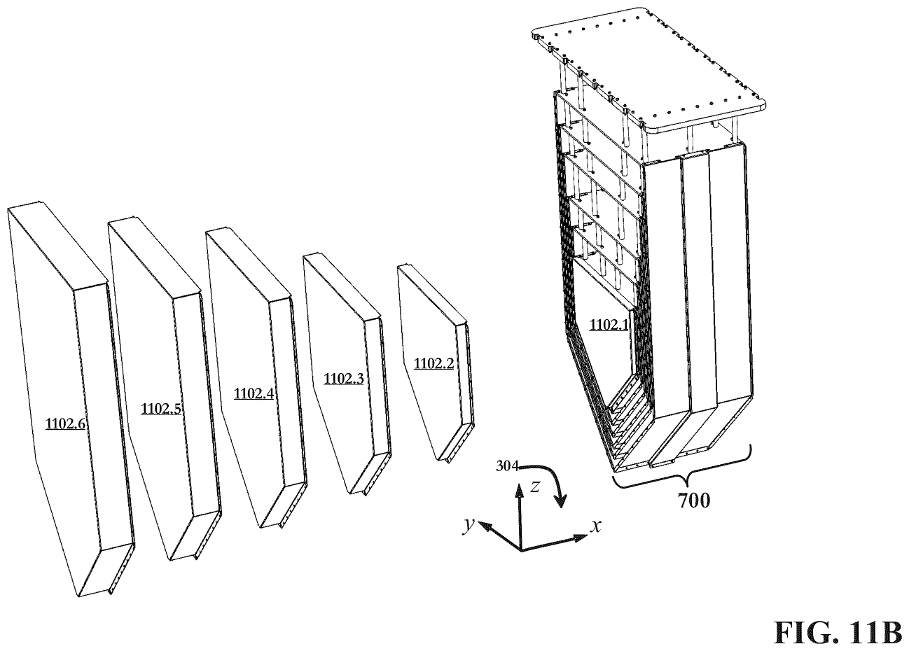

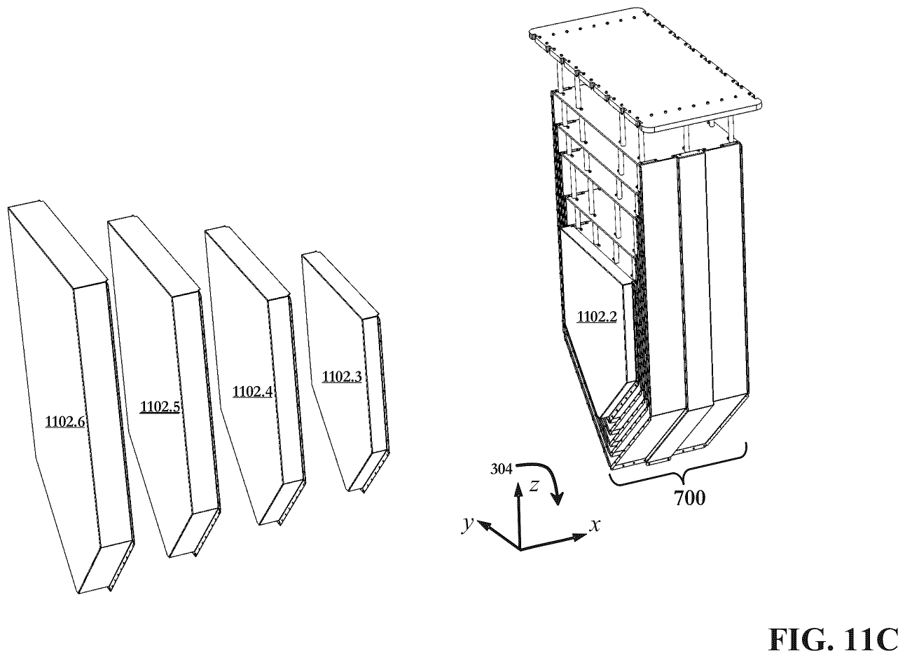

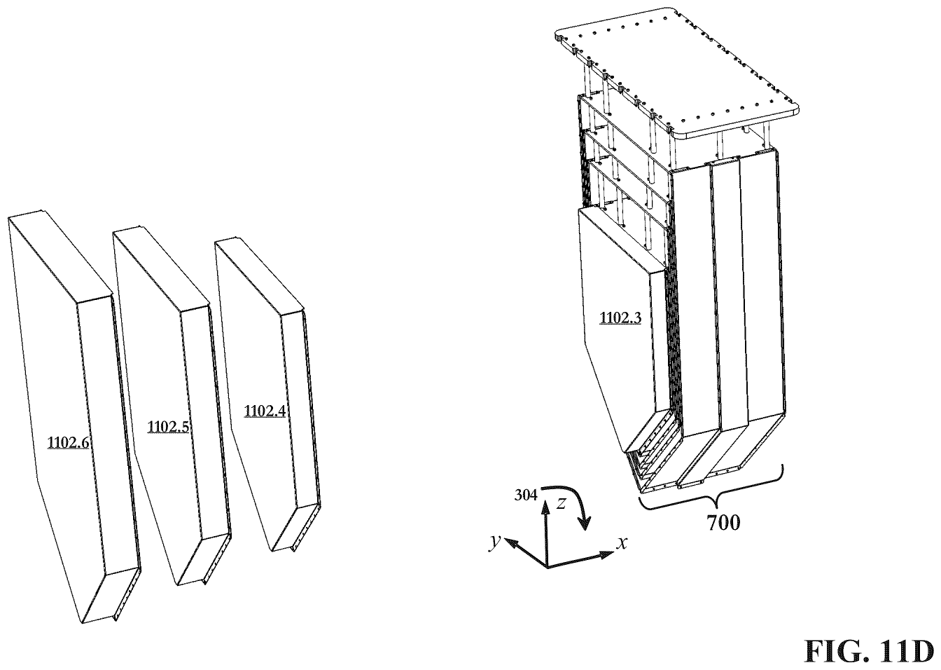

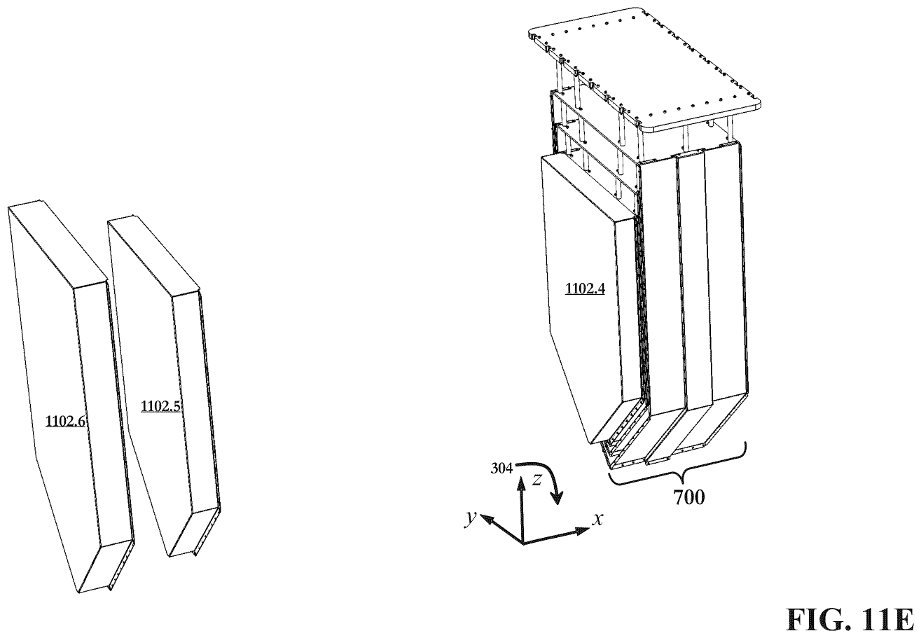

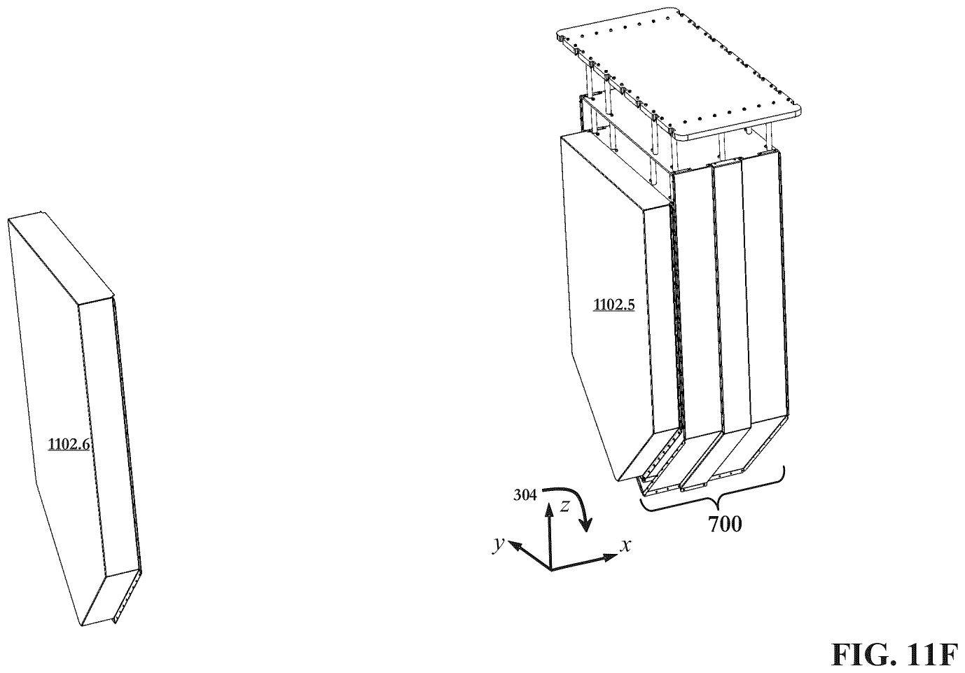

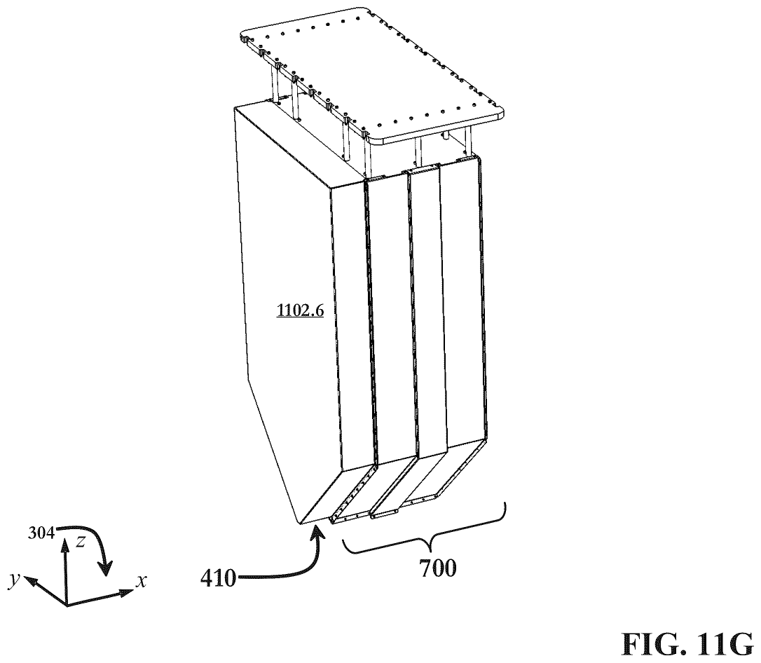

FIGS. 11A-11F illustrate exploded views of an end cell 302B or 302D in accordance with one or more embodiments described herein; FIG. 11G illustrates an assembled view thereof. Referring to FIG. 11A, which is an exploded illustration, each of the unit cells 302B and 302D (also known as B and D, respectively) can comprise a set 410 of end thermal shields, including a temperature T₁ shield 1102.1, a temperature T₂ shield 1102.2, a temperature T₃ shield 1102.3, a temperature T₄ shield 1102.4, a temperature T₅ shield 1102.5, and a temperature T₆ shield 1102.6. FIG. 11A illustrates unit cell B; unit cell D is similar. As illustrated by FIG. 11B through FIG. 11G, the end shields can mount sequentially: first, shield 1102.1 can mount upon thermal shell 702.1 as illustrated in FIG. 11B; second, shield 1102.2 can mount upon thermal shell 702.2 as illustrated in FIG. 11C; third, shield 1102.3 can mount upon thermal shell 702.3 as illustrated in FIG. 11D; fourth, shield 1102.4 can mount upon thermal shell 702.4 as illustrated in FIG. 11E; fifth, shield 1102.5 can mount upon thermal shell 702.5 as illustrated in FIG. 11F; and sixth, shield 1102.6 can mount upon thermal shell 702.6 as illustrated in FIG. 11G. Consequently, thermal shielding for all temperatures T₁ through T₆ can encase three sides of refrigerator 408 in end-cell B or D.

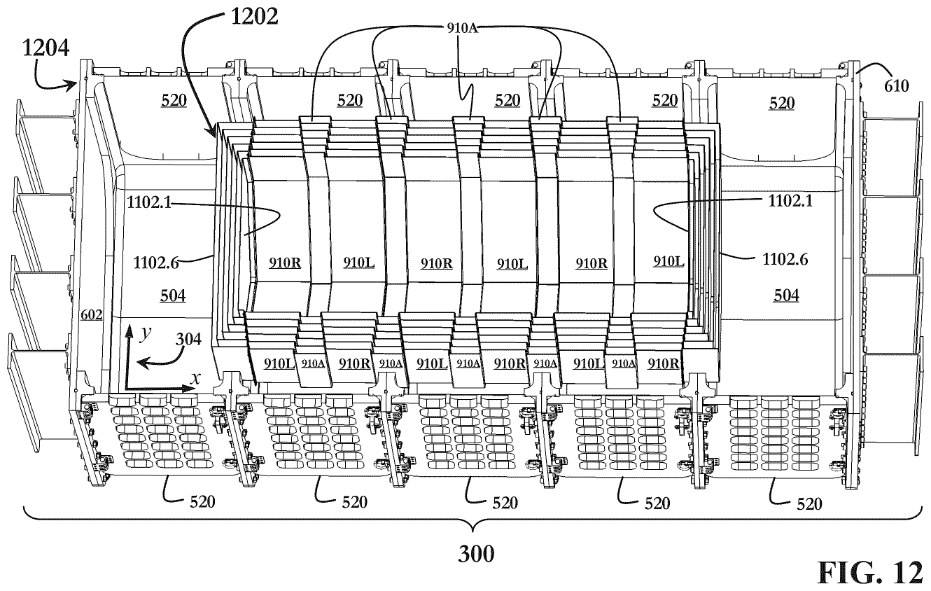

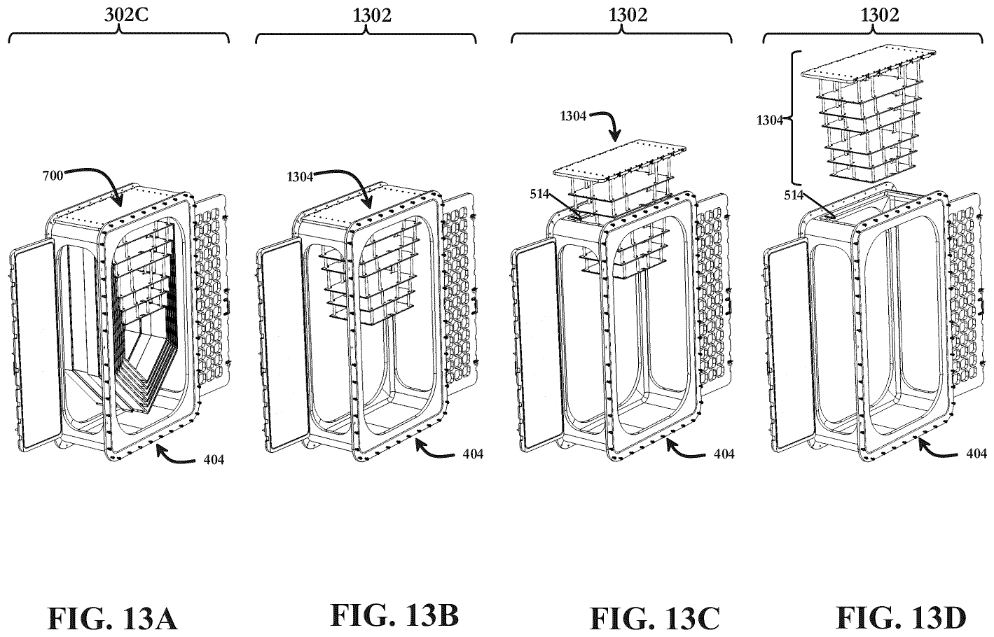

FIG. 12 illustrates a cutaway view of a modular cell embodiment in accordance with one or more embodiments described herein. As shown, FIG. 12 is a perspective view of generic embodiment 300 that is cutaway through a plane parallel to the xy plane of Cartesian coordinate system 304, with the value of z on the cut plane being slightly less than that of the −z face of plates 704.1 of refrigerators 408. Consequently, FIG. 12 illustrates a global set of thermal shields 1202, which can comprise six nested sets of thermal shields, one set for each of the temperatures T₁ through T₆, each set comprising a plurality of shields 910L, 910R, and 910A and end shields 1102. FIG. 12 illustrates that the width of shields 910A are graduated; that is, the width of all shields 910A in the T₁ shell are slightly narrower than those in the T₂ shell, which are narrower than those in the T₃ shell, and so on, with those in the T₆ shell being the widest. The purpose of the graduated widths is to allow assembly and disassembly of all shields 910L, 910R, and 910A of one FRU assembly 700 only, including shields 910A that are shared with adjoining FRU assemblies in neighboring unit cells, thereby to allow disassembly and removal of just one FRU for repair, as described further later in connection with FIG. 13B. FIG. 12 also illustrates a global vacuum enclosure 1204 that can comprise frames 504, doors 520, and end walls 602 and 610. Consequently, FIG. 12 illustrates an objective of generic embodiment 300: thermal shields 1202 and vacuum enclosure 1204 can be located on the periphery of the plurality of refrigerators 408, thereby providing one large, unified, evacuated, thermally shielded space in which equipment such as cryogenic quantum payloads may be housed with no barriers between payloads. That is, although it is composed of modular unit cells each with an instance of refrigerator 408, generic embodiment 300 will appear, to equipment placed therein, to be a single large refrigerator, such that electrical cables, optical cables, and other apparatus can easily connect between a collection of modularized equipment distributed among the unit cells. For example, as will be shown below, in a quantum-computer application, generic embodiment 300 is capable of being specialized to house quantum payloads distributed across the plurality of unit cells, with quantum-link cables connected payload to payload.

Unlike a monolithic large refrigerator, the goal of payload-to-payload interconnectivity can be achieved, with generic embodiment 300, in a modular, scalable manner that has several advantages. First, in comparison to a monolithic refrigerator, embodiment 300 can be practical to manufacture, transport, and install because each module (unit cell) can have a relatively small dimension in one direction; namely, unit-cell width p in the x direction is on the order of p=750 mm, such that a unit cell can be navigated through doorways. Second, the fact that p can be relatively small makes connections between payloads in neighboring unit cells relatively short. Third, the unit cell can be designed to be flexible, such that various types of refrigeration equipment, payload, and signal-delivery can be accommodated without re-designing any of the frame assembly except the skylight assembly. Fourth, generic embodiment 300 simplifies maintenance and repair, because, by virtue of skylight cutout 514, FRU assembly 700 can be removed for repair or replacement. Fifth, because generic embodiment 300 is modular, larger and larger collections of payloads can be accommodated merely by adding more unit cells C to array 300. This can be far preferable to designing and producing larger and larger monolithic refrigerators.

FIGS. 13A-D illustrate FRU removal for a modular cell embodiment in accordance with one or more embodiments described herein. As shown FIG. 13A through FIG. 13D, which depict a sequence of four steps by which FRU assembly 700 can be withdrawn from unit cell C (e.g., 302C) for purposes of servicing, repair, and/or FRU replacement. Withdrawal of FRU 700 from cells B and D can be similar. First, FIG. 13A illustrates unit cell C (e.g., 302C) as previously illustrated in FIG. 4. Second, FIG. 13B illustrates a shield-less version 1302 of unit cell C in which all thermal-shielding devices have been removed from FRU 700, including all instances of left shields 910L, right shields 910R, auxiliary shields 910A, and top trays 1002, thereby leaving a shield-less FRU 1304. Removal of the thermal-shielding devices 910L, 910R, 910A, and 1002 can be accomplished by reversing the assembly steps previously described in connection with FIG. 9, FIG. 10A, FIG. 10B, and FIG. 10C. Third, FIG. 13C illustrates shield-less unit cell 1302 with FRU 1304 partially withdrawn from frame assembly 404 using skylight cutout 514. Fourth, FIG. 13D illustrates shield-less unit cell 1302 with FRU 1304 fully withdrawn from frame assembly 404. Means for withdrawal of cell FRU 1304 are deliberately not illustrated in FIG. 13C and FIG. 13D, because such means are preferably designed in tandem with the specifics of a fully featured embodiment that derives from generic embodiment 300. Such a fully featured embodiment is shown below.

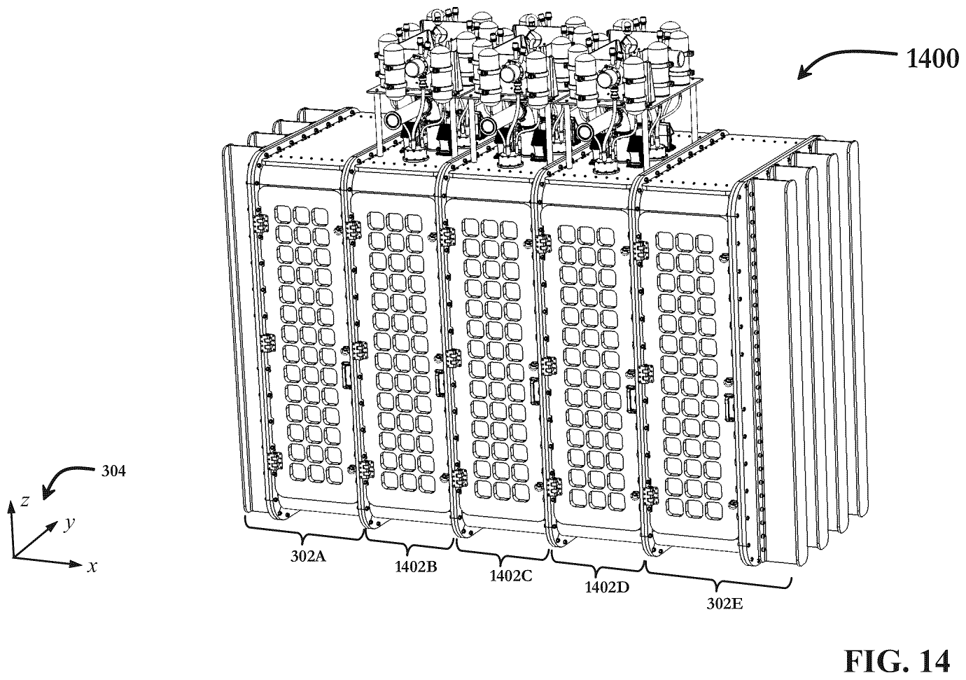

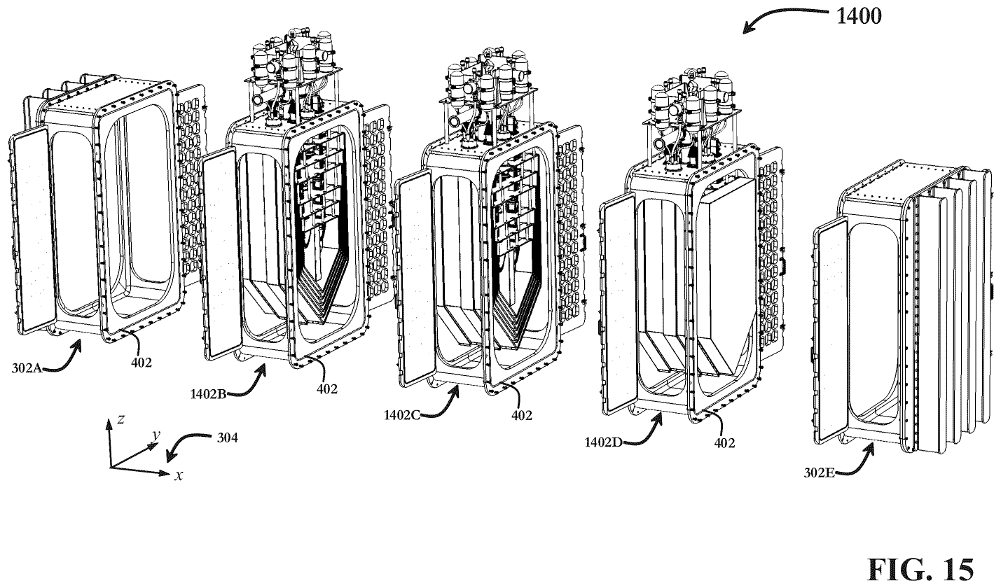

FIG. 14 illustrates an assembled view of a fully featured embodiment 1400 and FIG. 15 illustrates an exploded view of the fully featured embodiment 1400 in accordance with one or more embodiments described herein. In direct analogy to generic embodiment 300, fully featured embodiment 1400 can comprise a fully featured unit-cell array of five unit cells that can be arrayed, as for generic embodiment 300 in FIG. 3, at pitch p along the x direction of coordinate system 304. The fully featured unit-cell array can comprise the unpopulated, left-end unit cell 302A; a populated, fully featured left-thermal-shield unit cell 1402B; a populated, fully featured default unit cell 1402C; a populated, fully featured right-thermal-shield unit cell 1402D; and the unpopulated, right-end unit cell 302E. For brevity, these unit-cell variants can, as with the generic embodiment 300, be referred to succinctly by alphabetic suffix alone; that is 302A, 1402B, 1402C, 1402D, 302B can be referred to as “A”, “B”, “C”, “D”, and “E”, respectively, where underscores on B, C, and D indicate fully featured cells that differ, in ways specified below, from their counterparts B, C, D in generic embodiment 300. As in generic embodiment 300, adjacent cells {A B C D E} can be abutted to form a vacuum-tight seal therebetween by means of O-Rings 402 illustrated on FIG. 15.

As for the generic embodiment 300, the unit-cell array {A B C D E} shown in FIG. 14 and FIG. 15 is merely exemplary. Other possible arrangements include {A B D E}, {A B C₁ C₂ D E}, {A B C₁ C₂ C₃ D E}, and more generally, {A B C₁ C₂ . . . Cₙ D E}, where C₁, C₂, . . . , Cₙ are instances of C and n is any integer greater than or equal to zero. That is, embodiment 1400 can comprise n+2 populated cells {B C₁ C₂ . . . Cₙ D} and two unpopulated cells (A, E). Differences between the populated, fully featured unit cells B, C, D and their unit cell counterparts B, C, D can be illustrated by reciting the differences between C and C, which are representative of all three cases.

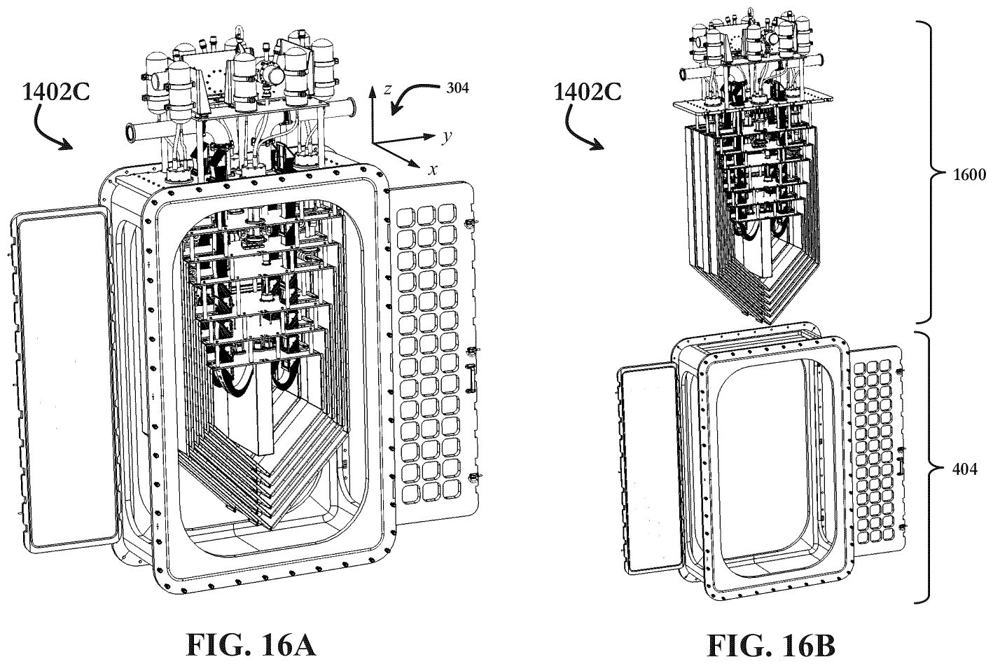

FIG. 16A illustrates an assembled view of fully featured default unit cell C (e.g., 1402C), and FIG. 16B illustrates an exploded view thereof. Fully featured cell C can comprise frame assembly 404 (identical to that in generic embodiment 300) and a fully featured FRU assembly 1600. FIG. 16B is an exploded analogue to unexploded FIG. 13A, in which cell C can comprise frame assembly 404 and cell FRU assembly 700.

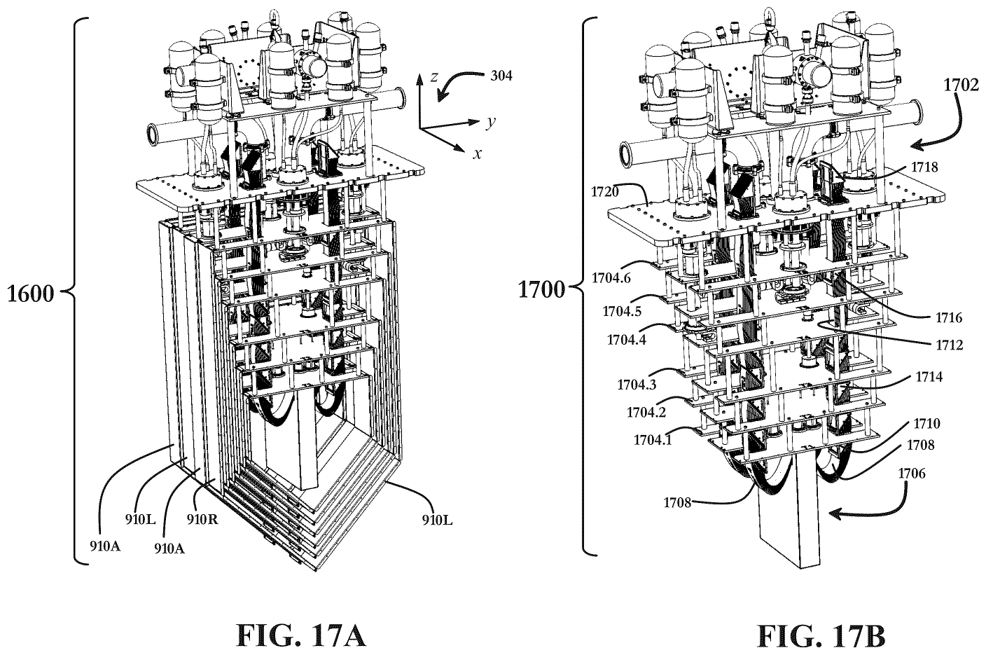

FIGS. 17A and 17B illustrate a fully featured FRU assembly of in accordance with one or more embodiments described herein. Referring to FIG. 17A, FRU assembly 1600 can comprise, on both sides (±y), and for each temperature T₁ through T₆, thermal shields 910L, 910A, and 910R that are identical to those in cell FRU assembly 700, as illustrated on exploded FIG. 9 and cutaway view FIG. 12.

FIG. 17B illustrates a shield-less FRU assembly 1700, which can be the same as FRU assembly 1600 except that FRU 1700 has all thermal shields 910L, 910A, 910R removed, thereby to allow FRU withdrawal as previously described for shield-less unit cell FRU 1304. FRU assembly 1700 also reveals more clearly how assembly 1600 can differ from assembly 700, as summarized by the following.

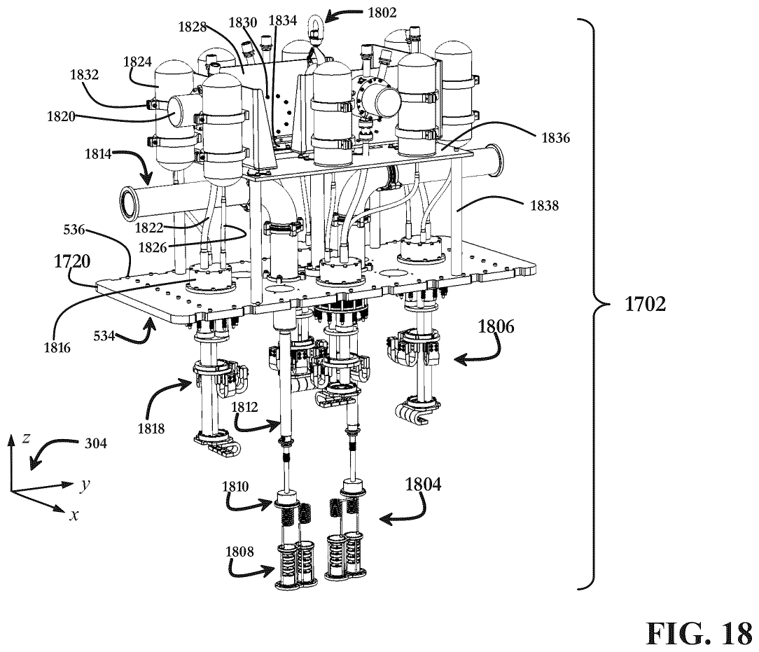

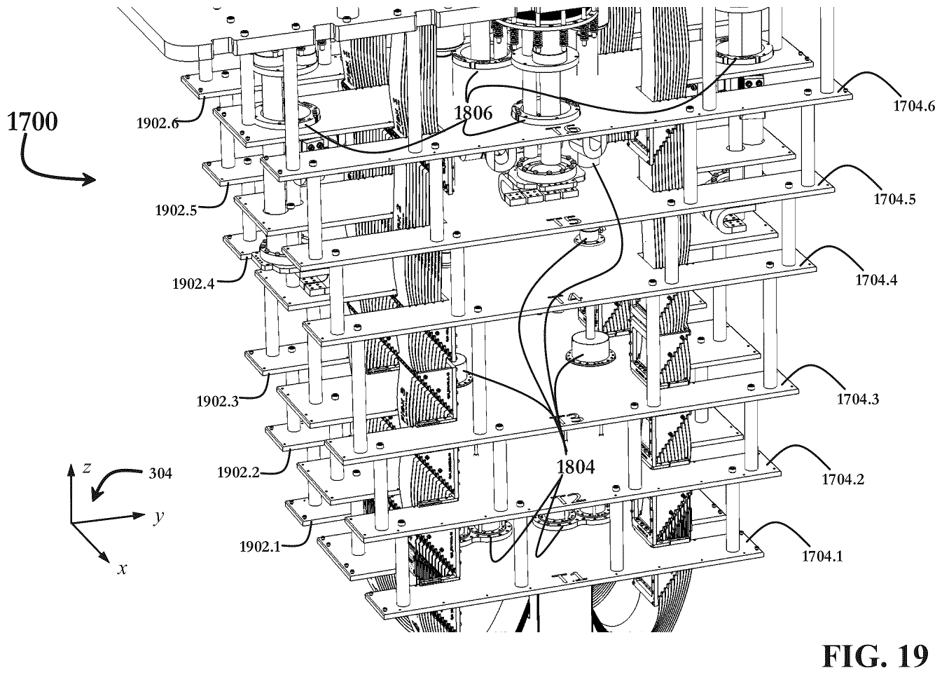

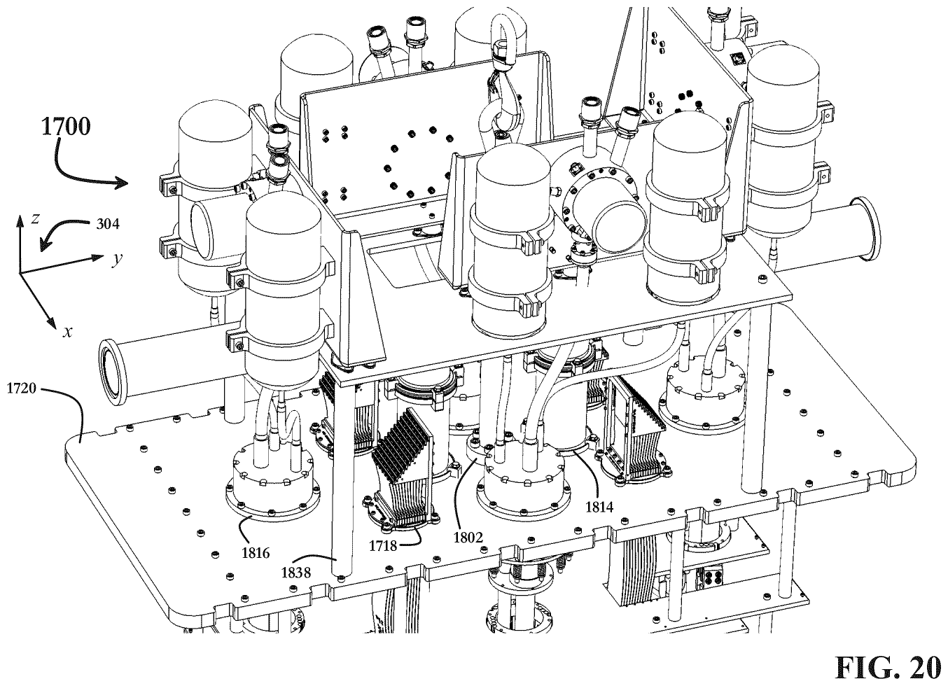

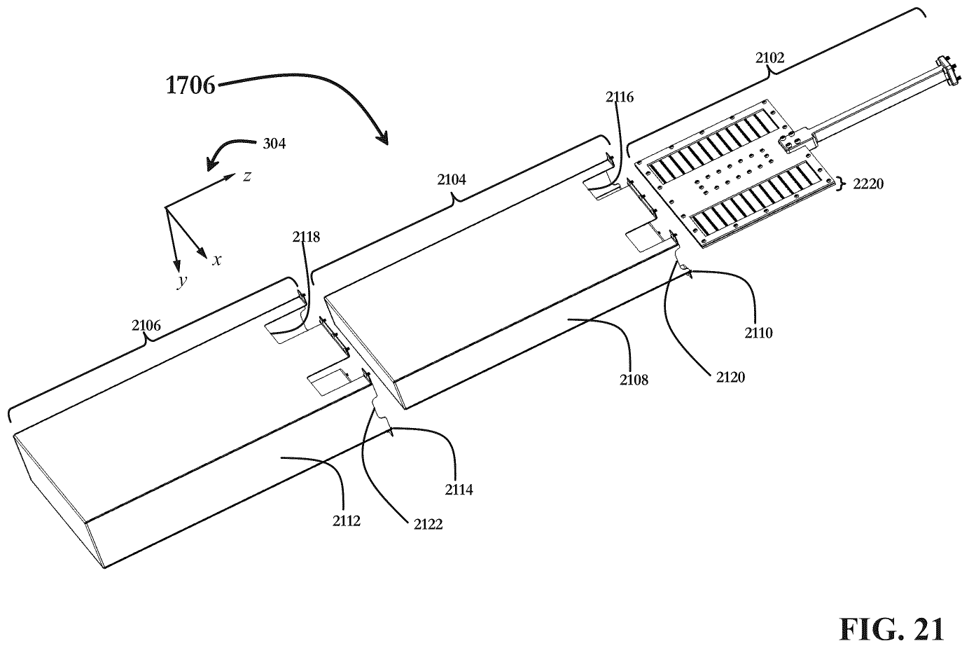

First, FRU assembly 1700 can comprise, instead of generic skylight assembly 502, a fully featured skylight assembly 1702, which is further illustrated on FIG. 18 and FIG. 20. Second, FRU assembly 1700 can comprise, instead of cell top plates 704.1 through 704.6, a set of fully featured top plates 1704, including a fully featured top plate 1704.1 held at temperature T₁, a fully featured top plate 1704.2 held at temperature T₂, a fully featured top plate 1704.3 held at temperature T₃, a fully featured top plate 1704.4 held at temperature T₄, a fully featured top plate 1704.5 held at temperature T₅, and a fully featured top plate 1704.6 held at temperature T₆. Differences between fully featured plates 1704 and cell plates 704 are illustrated on FIG. 19. Third, FRU assembly 1700 can comprise a payload assembly 1706, which is further illustrated on FIG. 21. Fourth, FRU assembly 1700 can comprise four instances of a plurality of lower cables 1708 that can extend from payload 1706 to a first connection means 1710 affixed to plate 1704.1, where each lower cable 1708 can be electrically connected to a corresponding upper cable 1712. Upper cables 1712 can begin at first connection means 1710, continue through a plurality of higher-temperature connection means such as 1714 (affixed to plate 1704.3) and 1716 (affixed to plate 1704.6), and end at a room-temperature connection means 1718 that is affixed to a fully featured skylight plate 1720. Using connection means 1718, a set of room temperature cables RTC (not shown) can be electrically connected to upper cables 1712. Thus, the three sets of cables 1708, 1712, and RTC, connected in series, can transmit electrical signals between payload assembly 1706 and a set of room-temperature electronics (not shown), which are external to embodiment 1400. Although FRU assembly 1700 shows four instances of cable sets 1708 and 1712, it should be understood that, in alternative embodiments, more or fewer instances thereof can be installed, depending on space available and on cabling needs of one or more payload assemblies 1706.

FIG. 18 illustrates a fully featured skylight assembly in accordance with one or more embodiments described herein. As shown in FIG. 18, fully featured skylight assembly 1702 can comprise fully featured skylight plate 1720, skylight screws 536 and skylight O-ring 534 as for the unit cell skylight assembly 502, a hoist assembly 1802 to enable withdrawal of FRU 1706, a plurality of lower-temperature of cooling means 1804 that enable the creation of temperatures T₁ through T₃ (e.g., temperatures between approximately 20 mK and approximately 700 mK), and a plurality of a higher-temperature cooling means 1806 that enable the creation of temperatures T₄ through T₆ (e.g., temperatures between approximately 4 K and approximately 77 K).

Each of the lower-temperature cooling means 1804, of which two are illustrated in FIG. 18, can be a dilution-refrigeration assembly that circulates a fluid mixture of ³He and ⁴He that is rich in ³He and is hereafter referred to simply as ³He. For example, lower-temperature cooling means 1804 can be the double dilution unit shown, and which comprises a double mixing chamber 1808, a still 1810, an internal-dilution-piping assembly 1812, and an external-dilution-piping assembly 1814. It should be appreciated that use of other cooling means, cooling fluid mixtures or compositions, and/or other cryogenic or dilutions apparatuses or refrigerators is envisioned. Furthermore, it should be appreciated that use of any temperature or temperature range is envisioned.

Each of the higher-temperature cooling means 1806, of which four are illustrated in FIG. 18, can comprise a pulse-tube assembly that circulates fluid ⁴He, or another suitable fluid or mixture. For example, cooling means 1806 can comprises a cold head 1816, an internal pulse-tube piping assembly 1818, an external motor 1820, a motor hose 1822, a pair of tanks 1824, and a pair of tank hoses 1826. To support motor 1820 and tanks 1824, each cooling means 1806 can further comprise a motor-and-tank mounting bracket 1828, a plurality of motor-mount screws 1830, a set of tank mounting rings 1832, a set of vibration isolators 1834, motor-and-tank mounting plate 1836, and motor-and-tank-mounting-plate standoffs 1838. In an embodiment, higher-temperature cooling means 1806 can pre-cool the ³He used by lower-temperature cooling means 1804, prior to further cooling thereby. In another embodiment, higher-temperature cooling means 1806 can utilize different cooling fluid mixtures or compositions for different temperature levels. For example, liquid He can be utilized for temperature T₄, gaseous He can be utilized for temperature T₅, and liquid N can be utilized for temperature T₆. It should be appreciated that use of other cooling means, cooling fluid mixtures or compositions, and/or other cryogenic or dilutions apparatuses or refrigerators is envisioned. Furthermore, it should be appreciated that use of any temperature or temperature range is envisioned.

FIG. 19 illustrates the fully featured, shield-less FRU assembly 1700 in accordance with one or more embodiments described herein. As shown in FIG. 19, fully featured top plate 1704.1 can differ from generic top plate 704.1 by the addition of a cutout 1902.1 for each instance of cable sets 1708 and 1712. Other fully featured top plates 1704.2, 1704.3, 1704.4, 1704.5, and 1704.6 can differ likewise, respectively, from generic top plates 704.2, 704.3, 704.4, 704.5, and 704.6. Moreover, all six fully featured top plates can differ from their generic counterparts by the addition of cutouts and tapped holes as required to mount cable connection means such as 1710, 1714, 1716, and 1718, and to accommodate cooling means 1804 and 1806.

FIG. 20 illustrates another view of the fully featured, shield-less FRU assembly 1700 in accordance with one or more embodiments described herein. As shown, fully featured skylight plate 1720 can differ from generic skylight plate 532 by the addition blind tapped holes to affix hoist assembly 1802, and by the addition of cutouts and blind tapped holes to accommodate and affix each instance of room-temperature connection means 1718, each instance of external piping 1814 of lower-temperature cooling means 1804, each instance of cold head 1816 and standoffs 1838 of higher-temperature cooling means 1806. It is anticipated that alternative embodiments can have entirely different arrangements of hoist means, cooling means, and connection means. For such an alternative embodiment, an alternative fully featured skylight can be used instead of 1720, but it can nevertheless be derived from generic skylight plate 532. Consequently, an advantage of the skylight plate is that it can decouple the design of the large, expensive frame assembly 404 from the details of hoist means, cooling means, and connection means: these means can change yet frame assembly 404 can remain the same.

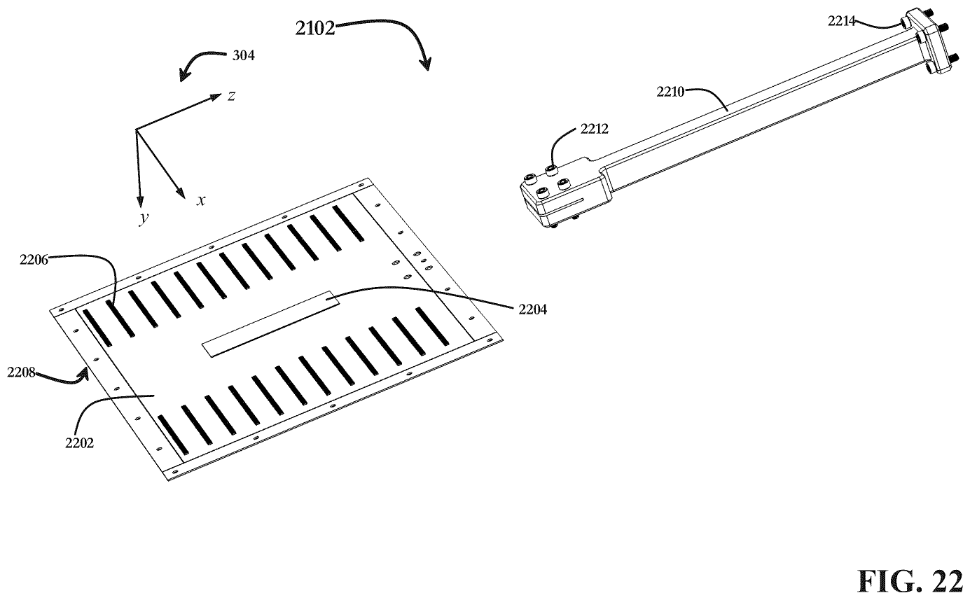

FIG. 21 illustrates an exploded view of a payload assembly of in accordance with one or more embodiments described herein. As shown, payload assembly 1706 can comprise a payload-electronics assembly 2102, an inner-magnetic-shield assembly 2104, and an outer-magnetic-shield assembly 2106. Payload-electronics assembly 2102 is further described on FIG. 22. Inner-magnetic-shield 2104 can comprise an inner magnetic shield 2108 and screws 2110 that affix shield 2108 to the −z surface of plate 1704.1 shown in FIG. 19. Likewise, outer-magnetic-shield 2106 can comprise an outer magnetic shield 2112 and screws 2114 that can affix shield 2112 to the −z surface of plate 1704.1. Magnetic shields 2108 and 2112 can be composed of high-magnetic-permeability material. Inner magnetic shield 2108 can comprise notches 2116 in the ty faces thereof to accommodate cables 1706; outer magnetic shield 2112 comprises similar notches 2118 for the same reason. Inner magnetic shield 2108 can further comprise notches 2120 in the ±x faces thereof to accommodate cables shown later; out magnetic shield 2112 can comprise similar notches 2122 for the same reason.

FIG. 22 illustrates an exploded view of a payload-electronics assembly of in accordance with one or more embodiments described herein. As shown, payload-electronics assembly 2102, can comprise substrate 2202 capable of carrying electrical signals; a chip assembly 2204; a plurality of front connectors 2206; a plurality of rear connectors 2208 (not visible); a suspension bar 2210; a plurality of lower suspension-bar screws 2212 that affix suspension bar 2210 to substrate 2202; and a plurality of upper suspension-bar screws 2214 that affix suspension bar 2222 to plate 1704.1 shown in FIG. 19. Chip 2204, front connectors 2206, and rear connectors 2208 can be electrically connected to substrate 2202.

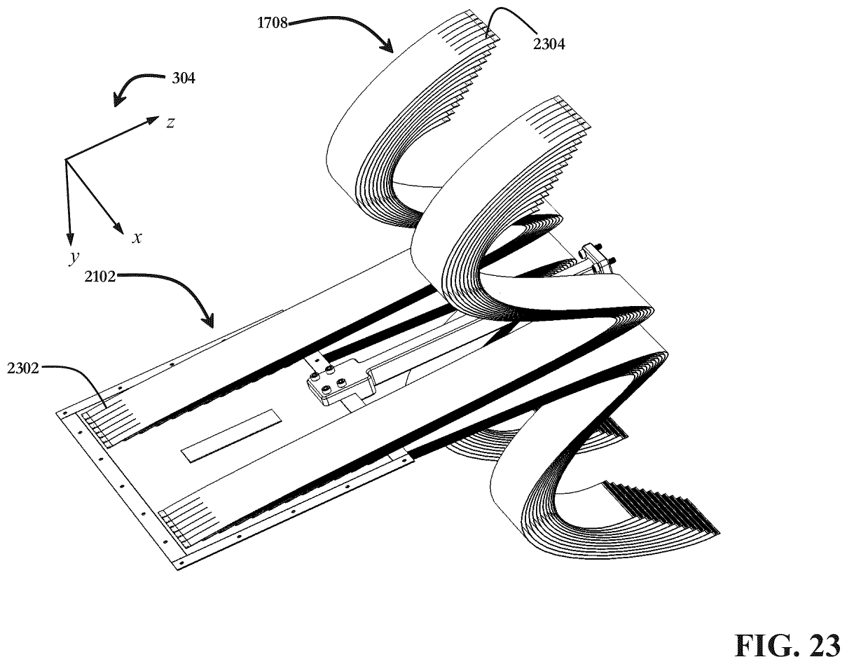

FIG. 23 illustrates an assembled view of a payload-electronics assembly and connecting cables in accordance with one or more embodiments described herein. As shown, FIG. 23 comprises an assembled diagram of payload-electronics assembly 2102 together with lower cables 1708, which are shown engaging front connectors 2206. Cables 1708 can comprise a first plurality of slits 2302 where the cables engage connectors 2206 and 2208. Cables 1708 can also comprise a second plurality of slits 2304 where the cables engage connection means 1710. Such slits 2302 and 2304 can be useful to relieve over-constraint in cases where multiple connectors engage each end of each cable. Chip assembly 2204 can be a quantum-computer payload (e.g., a quantum device), which can comprise a qubit chip comprising a plurality of superconducting qubits. In such a case, electrical signals delivered by cables 1708 can include qubit stimulus signals, qubit readout signals, as well as ancillary signals that improve the functioning of the qubits. These signals can be wired from connectors 2206 and 2208 to chip assembly 2204 via a plurality of wiring traces embedded in substrate 2202.

It is anticipated that payload assembly 1706 is merely exemplary. Other types, sizes, and shapes of payload assemblies can be accommodated by alternative embodiments derived from the generic embodiment. For example, if, for an alternative application, payload assembly 1706 is larger in the y direction than can be accommodated using the angle θ=135° shown in FIG. 9, then, as previously stated, θ can instead be otherwise, between the limits of θ=90° and θ=180°.

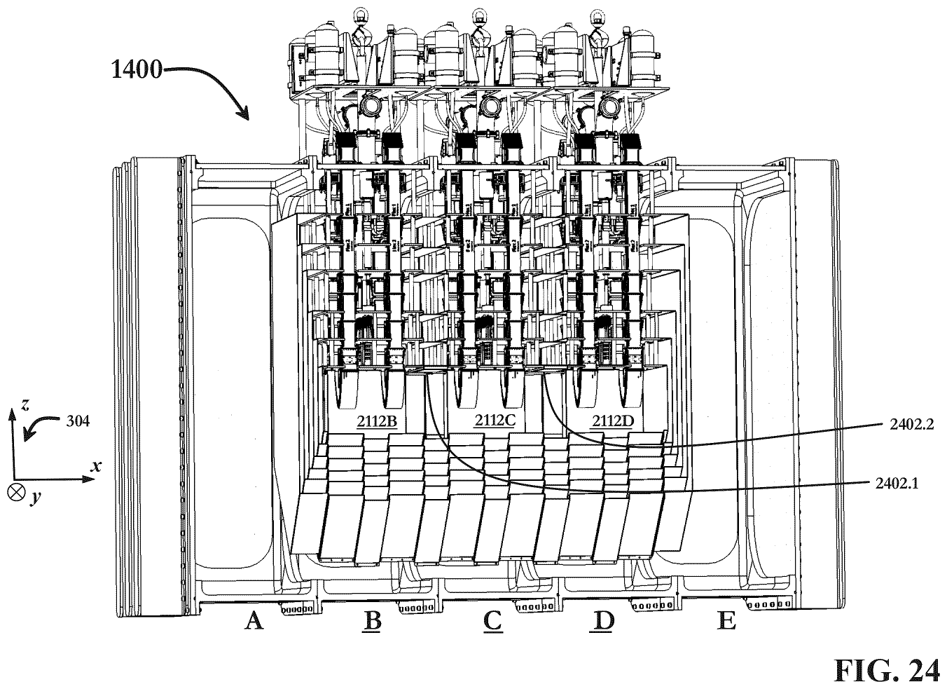

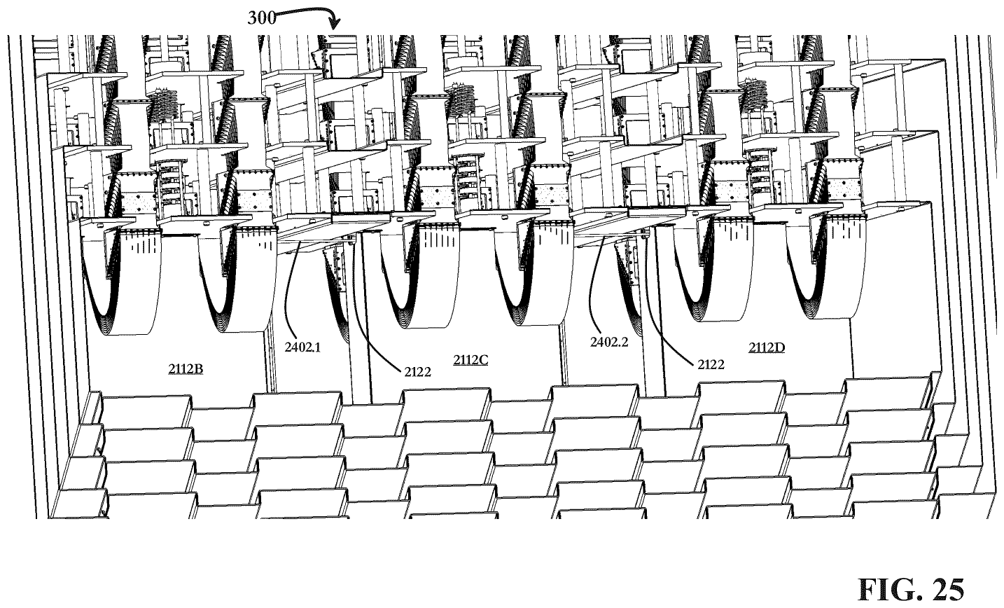

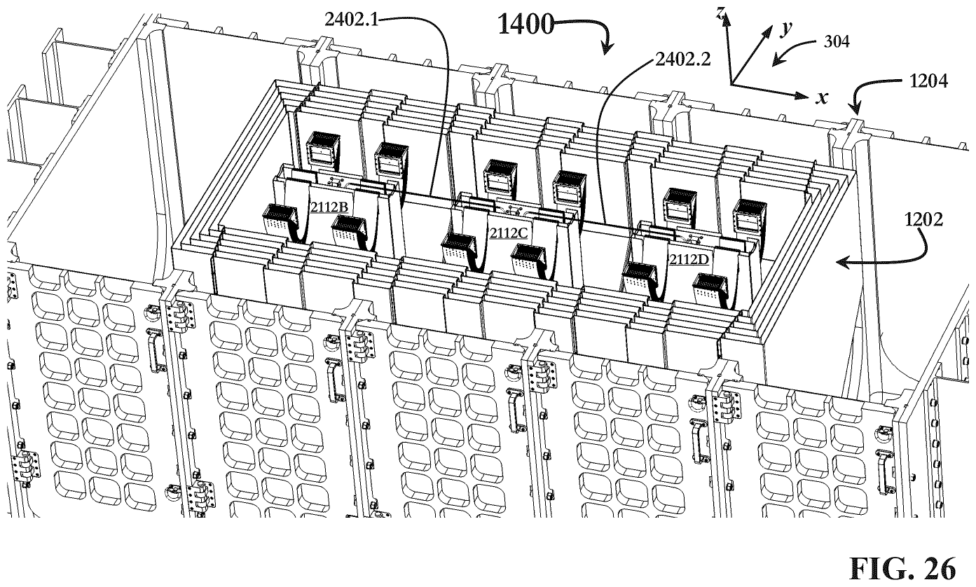

A fully featured embodiment comprising unit cells {A B C₁ C₂ . . . Cₙ D E} can comprise, between each adjacent pair of populated unit cells B, C, and D, a plurality of quantum-link cables 2402 that communicate cell to cell. Such quantum-link cables 2402 are illustrated in FIG. 24, FIG. 25, and FIG. 26. FIG. 24 is a cutaway view of embodiment 1400 in which the cut plane is parallel to the xz plane of Cartesian coordinate system 304, with the value of y on the cut plane being such as to hide the vertical portions of shields 910L, 910R, and 910A that would otherwise obscure payload assemblies 1706 for populated unit cells B, C, D, whose outer-magnetic-shields 2112 are marked as 2112B, 2112C, and 2112D, respectively. FIG. 25 is a magnified view of the central portion of FIG. 24. FIG. 26 is a cutaway view of embodiment 1400 in which the cut plane is parallel to the xy plane, where the value of z on the cut plane slightly less than that of the −z surface of plate 1704.1

Referring to FIG. 24, FIG. 25, and FIG. 26, a first set of quantum-link cables 2402.1 can communicate between payload assemblies 1706 in unit cells B and C. Likewise, a second set of quantum-link cables 2402.2 can communicate between payload assemblies 1706 in unit cells C and D. Quantum-link cables 2402 can be very beneficial for embodiment 1400, as well as for other embodiments having more or fewer unit cells, because the quantum-link cables can allow qubits in separate payloads to communicate with each other. Without such communication, much of the computer's power can be lost. As illustrated for fully featured embodiment 1400, quantum-link cables 2402 can pass from payload to payload because no inter-payload barriers exist, for three reasons. First, as explained in connection with FIG. 12, global thermal shields 1202 can achieve full thermal shielding of each payload without payload-to-payload barriers that would exist in a conventional system such as juxtaposition 200 of two conventional cryostats. Second, as also explained in connection with FIG. 12, global vacuum enclosure 1204 can provide an evacuated environment for all payloads without the vacuum-can barriers that exist in conventional juxtaposition 200. Third, notches 2120 and 2122 illustrated on FIG. 25 can ensure, respectively, that magnetic shields 2108 and 2112 do not pose barriers hindering the passage of quantum-link cables 2402 between payloads.

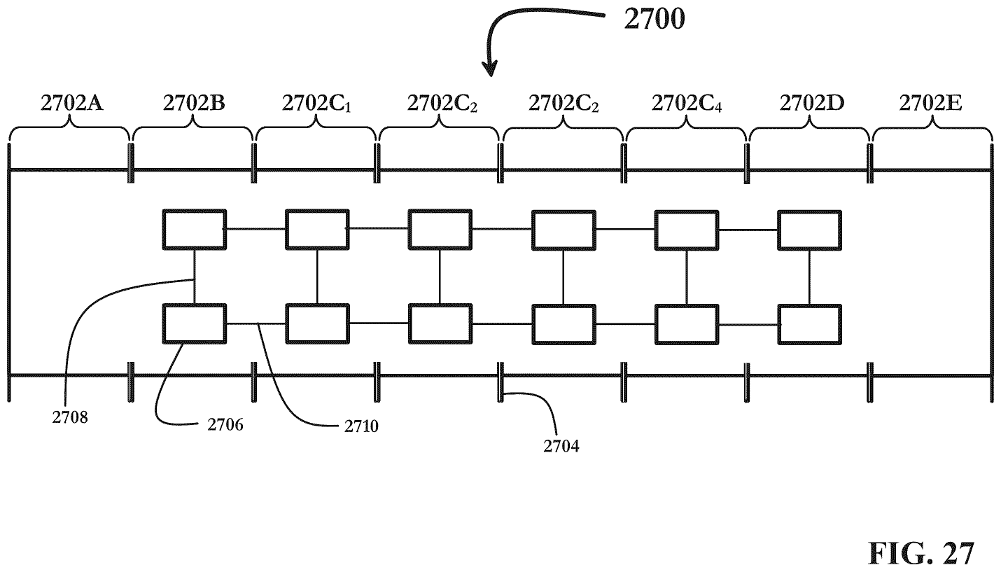

It is anticipated that many variations of the embodiments described above are possible. For example, FIG. 27 schematically illustrates a cutaway top view of an embodiment 2700 comprising a plurality of unit cells 2702A, 2702B, 2702C₁, 2702C₂, 2702C₃, 2702C₄, 2702D, 2702E, which are analogous to unit cells A, B, C₁, C₂, C₃, C₄, D, E, respectively, of embodiments previously described. As detailed previously, adjacent unit cells can be joined to each other in a vacuum-tight fashion using O-rings and bolt in flanges 2704, which are analogous to flanges 516L and 516R of FIG. 5. Embodiment 2700 can comprise a plurality of m payloads 2706 in each of the populated unit cells 2702B, 2702C₁, 2702C₂, 2702C₃, 2702C₄, 2702D; the plurality illustrated is m=2, but m can be any positive integer. Embodiment 2700 can further comprise, between payloads within each unit cell, a plurality of quantum-link cables 2708, and can also comprise, between payloads in adjoining unit cells, a plurality of quantum-link cables 2710.

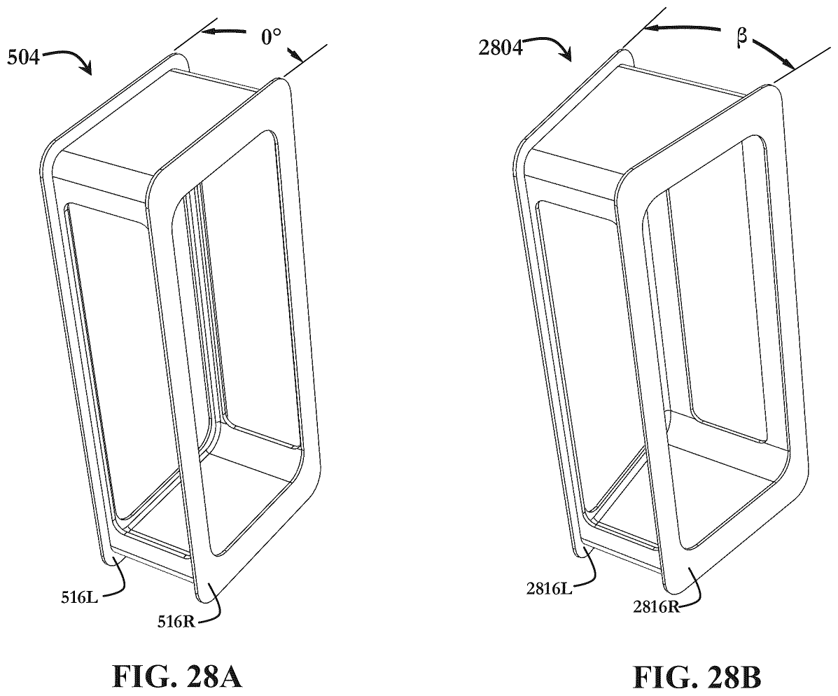

As a another example, consider a large embodiment comprising a collection of unit cells (A B C₁ C₂, . . . , Cₙ, D E} in which n is large. Such an embodiment may benefit from avoiding the straight, linear array of unit cells illustrated heretofore, because a linear layout of the large embodiment may not fit in a building intended to house it. Avoiding a linear layout can be accomplished by replacing, for one or more unit cells, the parallel frame 504 (shown heretofore, and also in FIG. 28A) with a wedge frame 2804 shown in FIG. 28B. Wedge frame 2804 comprises a left flange 2816L and a right flange 2816R whose outer surfaces form a non-zero angle β. This distinguishes wedge frame 2804 from parallel frame 504, for which the corresponding angle, between left flange 516L and right flange 516R, is zero degrees, as shown in FIG. 28A. For the wedge frame 2804 illustrated in FIG. 28B, β=15°. Other values of β are possible, but it is useful if B is an integer submultiple of 90°. That is, it is useful if Kβ=90°, where K is an integer, because then abutting K wedge frames turns 90°, as will be shown presently.

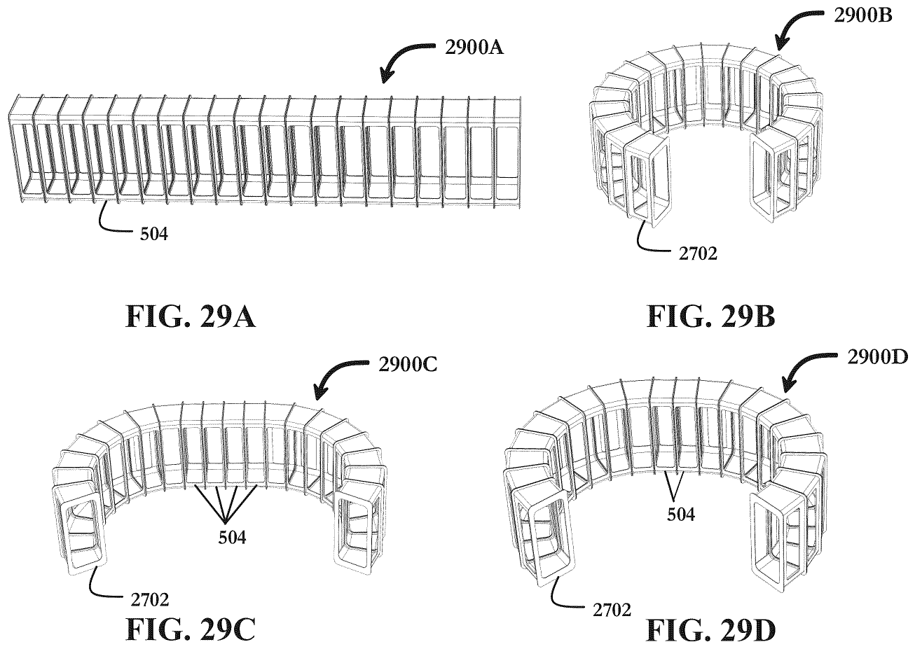

Using various combinations of wedge frames 2804 and parallel frames 504, a large embodiment can take many shapes potentially useful for deployment in various buildings in which the embodiment may be housed. For example, FIGS. 29A-29D illustrate four arrangements 2900A, 2900B, 2900C, and 2900D, respectively, of a 20-unit-cell embodiment: FIG. 29A illustrates a first arrangement in which all 20 unit cells employ parallel frames 504; FIG. 29B illustrates a second arrangement in which all 20 unit cells employ wedge frames 2804; FIG. 29C illustrates a third arrangement in which the centermost four unit cells employ parallel frames 504 and the remaining 16 unit cells employ wedge frames 2804; and FIG. 29D illustrates a fourth arrangement in which the centermost two unit cells employ parallel frames 504 and the remaining 18 unit cells employ wedge frames 2804. Many other arrangements are possible.

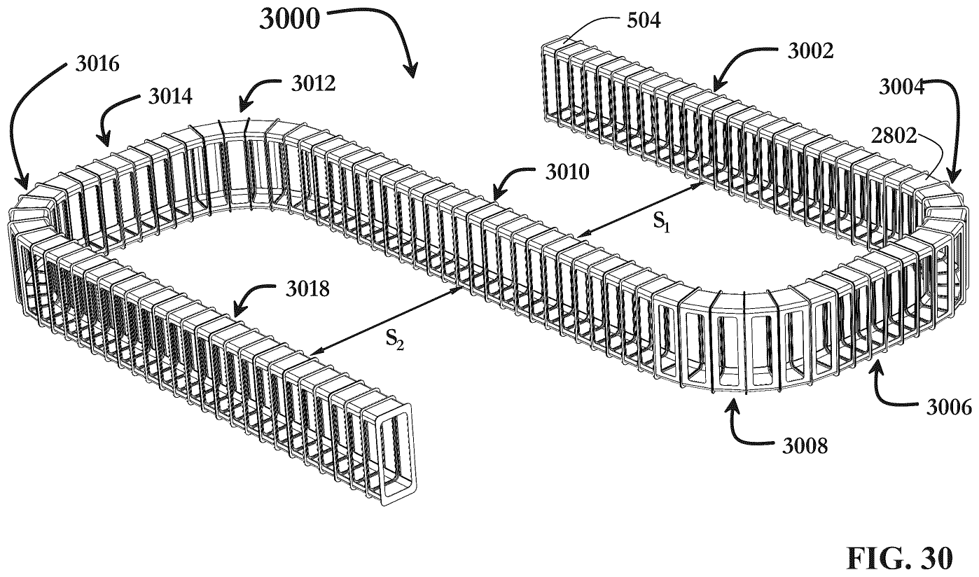

FIG. 30 illustrates a serpentine-shaped embodiment 3000 comprising one hundred and eight unit cells, which further exemplifies the usefulness of combining wedge frames 2804 and parallel frames 504. As illustrated, embodiment 3000 comprises a first portion 3002 that comprises parallel frames 504, a second portion 3004 abutted to 3002 that comprises wedge frames 2804, a third portion 3006 abutted to 3004 that comprises parallel frames 504, fourth portion 3008 abutted to 3006 that comprises wedge frames 2804, a fifth portion 3010 abutted to 3008 that comprises parallel frames 504, a sixth portion 3012 abutted to 3010 that comprises wedge frames 2804, a seventh portion 3014 abutted to 3012 that comprises parallel frames 504, an eighth portion 3016 abutted to 3014 that comprises wedge frames 2804, and a ninth portion 3018 abutted to 3016 that comprises parallel frames 504. In each of the portions 3004, 3008, 3012, and 3016, six wedge frames 2804 are used to turn a 90° corner. This is a consequence of wedge angle β=15° used for illustration; more generally, if Kβ=90°, then K wedge frames 2804 would be used in each of these portions. The number of parallel frames 504 in each of the portions 3002, 3006, 3010, 3014, 3018 may be varied to obtain different shapes, thereby to accommodate a building in which embodiment 3000 can be housed. Furthermore, the number of parallel frames 504 used in short portions 3006 and 3014 may be varied to obtain different values of the distances S₁ and S₂ between long portions 3002, 3010, 3018 of the serpentine shape. This is useful to provide space between said long portions for ancillary equipment. For example, in quantum computing applications, the ancillary equipment can include refrigeration equipment (not shown), room-temperature electronics (not shown) that can service the quantum payloads in the unit cells, and classic-computer equipment (not shown) that can be used in conjunction with the quantum computer.

Embodiments of the present invention may be a system, a method, and/or an apparatus at any possible technical detail level of integration. What has been described above includes mere examples of systems, methods, and apparatus. It is, of course, not possible to describe every conceivable combination of components or computer-implemented methods for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings, such terms are intended to be inclusive in a manner similar to the term “comprising” as “comprising” is interpreted when employed as a transitional word in a claim.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter disclosed herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While certain example embodiments have been described, these embodiments have been presented by way of example only, and are not intended to limit the scope the disclosures herein. Thus, nothing in the foregoing description is intended to imply that any particular feature, characteristic, step, module, or block is necessary or indispensable. Indeed, the novel methods and systems described herein may be embodied in a variety of other forms; furthermore, various omissions, substitutions and changes in the form of the methods and systems described herein may be made without departing from the spirit of the disclosures herein. The accompanying claims and their equivalents are intended to cover such forms or modifications as would fall within the scope and spirit of certain of the disclosures herein.

What is claimed is:

1. A cryogenic system comprising:
a plurality of unit cells joined together, wherein each unit cell comprises:
a frame; and
at least one temperature shell, wherein frames from adjacent unit cells are connected in a vacuum-tight manner to form a continuous, global vacuum enclosure, and temperature shells from adjacent unit cells are connected to form a continuous, global temperature shell.

2. The system of claim 1, wherein each unit cell further comprises at least one cryogenic cooling unit and at least one cryogenic payload that is cooled by the cooling unit.

3. The system of claim 1, wherein the global temperature shell has a cross-sectional area variance within 50%.

4. The system of claim 2, further comprising at each end of the plurality of unit cells
an end frame, wherein the plurality of frames and end frames together form a vacuum-tight vessel; and
an end cap for the global temperature shell at each end of the plurality of unit cells, wherein the global temperature shell and end caps form a substantially closed, radiation-resistant thermal enclosure.

5. The system of claim 4, wherein the at least one temperature shell comprises a top plate and a collection of side panels mounted to the top plate.

6. The system of claim 5, wherein the at least one top plate, the at least one cryogenic cooling unit, and the at least one cryogenic payload can be removed from the frame.

7. The system of claim 2, wherein the at least one cryogenic payload comprises a quantum device.

8. The system of claim 7, further comprising at least one superconducting link cable coupled to a first quantum device of a first unit cell in the plurality of unit cells and to a second quantum device of a second unit cell in the plurality of unit cells.

9. The system of claim 8, wherein the superconducting link cable is located within the thermal enclosure.

10. A cryogenic system comprising:
a plurality of unit cells joined together, wherein each unit cell comprises:
a frame;
a plurality of nested temperature shells at a plurality of temperature levels;
at least one cryogenic cooling unit; and
at least one cryogenic payload located within at least one of the temperature levels, that is cooled by the at least one cryogenic cooling unit, wherein frames from adjacent unit cells are connected in a vacuum-tight manner to form a continuous, global vacuum enclosure, and at each temperature level, temperature shells from the adjacent unit cells are connected to form a continuous, global temperature shell.

11. The system of claim 10, wherein each global temperature shell has a cross-sectional area variance within 50%.

12. The system of claim 10, further comprising, at each end of the plurality of unit cells:
an end frame, wherein the plurality of frames and end frames together form a vacuum-tight vessel; and
an end cap for each global temperature shell at each end of the plurality of unit cells, wherein, at each temperature level, the global temperature shell and end caps together form a substantially closed, radiation-resistant thermal enclosure.

13. The system of claim 10, wherein each of the plurality of temperature shells comprises a top plate and a collection of side panels mounted thereto.

14. The system of claim 13, wherein the plurality of top plates, the at least one cryogenic cooling unit, and the at least one cryogenic payload may together be removed from the frame.

15. A cryogenic system comprising:
a plurality of unit cells joined together, wherein each unit cell comprises:
a frame assembly comprising at least one door that forms a vacuum-tight seal when closed;
at least one temperature shell suspended from the frame assembly;
at least one cryogenic cooling unit; and
at least one cryogenic payload located within the at least one temperature shell, wherein frames from adjacent unit cells are connected in a vacuum-tight manner to form a continuous, global vacuum enclosure, and temperature shells from the adjacent unit cells are connected to form a continuous, global temperature shell.

16. The system of claim 15, wherein the at least one door opens to allow access to the at least one temperature shell and to the at least one cryogenic payload.

17. The system of claim 15, further comprising at each end of the plurality of unit cells:
an end frame, wherein the plurality of frames and end frames together form a vacuum-tight vessel; and
an end cap for the global temperature shell at each end of the plurality of unit cells, wherein the global temperature shell and end caps form a substantially closed, radiation-resistant thermal enclosure.

18. The system of claim 17, wherein the at least one temperature shell comprises a top plate and a collection of side panels mounted to the top plate.

19. The system of claim 5, wherein the top plate, the at least one cryogenic cooling unit, and the at least one cryogenic payload can be removed from the frame.

20. The system of claim 15, wherein the at least one cryogenic payload comprises a quantum device.
